(19) United States
(12) Patent Application Publication
(10) Pub. No.: US 2025/0169128 A1
(43) Pub. Date: May 22, 2025

(54) GATE TRENCH POWER SEMICONDUCTOR DEVICES WITH DEEP JFET PATTERNS

(71) Applicant: Wolfspeed, Inc., Durham, NC (US)

(72) Inventors: Naeem Islam, Morrisville, NC (US); Woongsun Kim, Cary, NC (US); Madankumar Sampath, Morrisville, NC (US); Sei-Hyung Ryu, Cary, NC (US)

(21) Appl. No.: 18/510,734

(22) Filed: Nov. 16, 2023

(51) Int. Cl. H01L 29/06; H01L 21/04; H01L 29/10; H01L 29/16; H01L 29/66; H01L 29/78

(52) U.S. Cl. CPC H10D 62/111; H01L 21/0465; H10D 12/031; H10D 30/668; H10D 62/393; H10D 62/8325

(57) ABSTRACT

A semiconductor device comprises a semiconductor layer structure comprising a drift region having a first conductivity type, a well region having a second conductivity type on the drift region, and a first JFET region having the first conductivity type, and a gate trench extending into the semiconductor layer structure. An upper surface of the first JFET region is positioned below the gate trench. A first conductivity dopant concentration of the first JFET region exceeds a first conductivity dopant concentration of the drift region.

### FIELD OF THE INVENTION

The present invention relates to power semiconductor devices and, more particularly, to power semiconductor devices having gate trenches and to methods of fabricating such devices.

### BACKGROUND

The Metal Oxide Semiconductor Field Effect Transistor (“MOSFET”) is a well-known type of semiconductor transistor that may be used as a switch. A MOSFET is a three terminal device that has gate, drain and source terminals and a semiconductor body. The semiconductor body is referred to herein as a “semiconductor layer structure” and may include one or more semiconductor layers/regions. A source region and a drain region are formed in the semiconductor layer structure that are separated by a channel region. A gate electrode (which may act as the gate terminal or be electrically connected to the gate terminal) is disposed adjacent the channel region and separated from the channel region by a thin oxide layer. A MOSFET may be turned on or off by setting a bias voltage that is applied to the gate electrode to be above or below a threshold value. When a MOSFET is turned on (i.e., it is in its “on-state”), current is conducted through the channel region between the source and drain regions. When the bias voltage is reduced below the threshold level, the current ceases to conduct through the channel region.

An n-type MOSFET has source and drain regions that have n-type (electron) conductivity and a channel region that has p-type (hole) conductivity (i.e., an “n-p-n” design). An n-type MOSFET turns on when a gate bias voltage is applied to the gate electrode that is sufficient to create a conductive n-type inversion layer in the p-type channel region, thereby electrically connecting the n-type source and drain regions and allowing for majority carrier conduction therebetween. A p-type MOSFET has a “p-n-p” design (i.e., p-type source and drain regions and an n-type channel region) and turns on when a gate bias voltage is applied to the gate electrode that is sufficient to create a conductive p-type inversion layer in the n-type channel region to electrically connect the p-type source and drain regions. Herein, the terms “first conductivity type” and “second conductivity type” are used to indicate either n-type or p-type, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity.

As noted above, the gate electrode of a MOSFET is separated from the channel region by a thin oxide layer that is called a gate oxide layer. Other non-oxide gate dielectric layers may be used in certain applications in place of the gate oxide layer. It will be appreciated that the techniques according to embodiments of the present invention that are described herein are equally applicable to devices having gate dielectric layers formed with materials other than oxides.

Because the gate electrode of a MOSFET is insulated from the channel region by the gate oxide layer, minimal gate current is required to maintain the MOSFET in its on-state or to switch the MOSFET between its off-state and its on-state. The gate current is kept small during switching because the gate forms a capacitor with the channel region. Thus, only minimal charging and discharging current is required during switching, allowing for less complex gate drive circuitry and faster switching speeds. MOSFETs may be stand-alone devices or may be combined with other circuit devices. For example, an Insulated Gate Bipolar Transistor (“IGBT”) is a semiconductor device that includes both a MOSFET and a Bipolar Junction Transistor (“BJT”) that combines the high impedance gate electrode of the MOSFET with the small on-state conduction losses that may be provided by a BJT. An IGBT may be implemented, for example, as a Darlington pair that includes a high voltage n-channel MOSFET at the input and a BJT at the output. The base current of the BJT is supplied through the channel of the MOSFET, thereby allowing a simplified external drive circuit (since the drive circuit only charges and discharges the gate electrode of the MOSFET).

In some applications, MOSFETs may need to carry large currents and/or be capable of blocking high voltages. Such MOSFETs are often referred to as “power” MOSFETs. Power MOSFETs are often fabricated from wide band-gap semiconductor materials (herein, the term “wide band-gap semiconductor” encompasses any semiconductor having a band-gap of at least 1.4 eV). Power semiconductor devices are often formed in silicon carbide (“SiC”), which has a number of advantageous characteristics including, for example, a high electric field breakdown strength, high thermal conductivity, high electron mobility, high melting point and high-saturated electron drift velocity.

Power semiconductor devices such as power MOSFETs can have a lateral structure or a vertical structure. In a device having a lateral structure, the terminals of the device (e.g., the drain, gate and source terminals for a power MOSFET) are on the same major surface (i.e., top or bottom) of a semiconductor layer structure. In contrast, in a device having a vertical structure, at least one terminal is provided on each major surface of the semiconductor layer structure (e.g., in a vertical MOSFET, the source and gate may be on the top surface of the semiconductor layer structure and the drain may be on the bottom surface of the semiconductor layer structure). The semiconductor layer structure may or may not include an underlying substrate such as a growth substrate.

The semiconductor layer structure of a power semiconductor device typically includes an “active region” in which one or more functional semiconductor devices are formed. The active region acts as a main junction for blocking voltage during reverse bias (off-state) operation and for providing current flow during forward bias (on-state) operation. The power semiconductor device may also have an edge termination structure such as guard rings or a junction termination extension in a termination region of the semiconductor layer structure that is adjacent (and typically surrounding) the active region. The edge termination structure may, among other things, reduce electric field crowding effects that can occur at the outer edges of a power semiconductor device. Typically, multiple power semiconductor devices are formed in/on a common wafer, and each power semiconductor device will typically have its own edge termination structure. After the wafer is fully processed, the resultant structure may be diced to separate the individual edge-terminated power semiconductor devices. Each power semiconductor device may have a unit cell structure in which the active region of each power semiconductor device includes a plurality of individual “unit cell” devices that are electrically connected in parallel and that together function as a single power semiconductor device.

Vertical power semiconductor devices that include a MOSFET can have a planar gate electrode design in which the gate electrode of the transistor is formed on top of the semiconductor layer structure or, alternatively, may have at least a portion of the gate electrode in a gate trench within the semiconductor layer structure, which are typically referred to as gate trench MOSFETs. With the planar gate electrode design, the channel region of each unit cell transistor is horizontally disposed underneath the gate electrode. In contrast, in the gate trench MOSFET design, the channels are typically vertically disposed adjacent sidewalls of the gate electrodes. Gate trench MOSFETs may provide enhanced performance, but typically require a more complicated manufacturing process.

One failure mechanism for a power MOSFET is the so-called “breakdown” of the gate oxide layer. The gate oxide layer is subjected to high electric fields during normal device operation. The stress on the gate oxide layer caused by these electric fields generates defects in the oxide material, and these defects build up over time. When the concentration of defects reaches a critical value, a so-called “percolation path” may be created through the gate oxide layer that electrically connects the gate electrode to the source or drain region, thereby creating a short-circuit that can destroy the device. The “lifetime” of a gate oxide layer (i.e., how long the device can be operated before breakdown occurs) is a function of, among other things, the magnitude of the electric field that the gate oxide layer is subjected to and the length of time for which the electric field is applied. FIG. 1 is a schematic graph illustrating the relationship between the operating time until breakdown occurs (the “gate oxide lifetime”) and the level of the electric field applied to the gate oxide layer. This graph assumes that the same electric field is always applied (which is not necessarily the case). As shown in FIG. 1, the relationship may, in some cases, be generally linear when the gate oxide lifetime is plotted on a logarithmic scale. The important point to take from FIG. 1 is that as the electric field level is increased, the lifetime of the gate oxide layer decreases exponentially. The lifetime of the gate oxide layer may be increased by increasing the thickness of the gate oxide layer, but various performance parameters of a MOSFET may be a function of the thickness of the gate oxide layer and thus increasing the thickness of the gate oxide layer is typically not an acceptable way of increasing the lifetime of the gate oxide layer.

### SUMMARY

Pursuant to some embodiments of the present invention, semiconductor devices are provided that comprise a semiconductor layer structure comprising a drift region having a first conductivity type, a well region having a second conductivity type on the drift region, and a first junction field effect (“JFET”) pattern having the first conductivity type. First and second gate trenches extend into the semiconductor layer structure. The first JFET pattern comprises a plurality of first JFET regions, where a first of the first JFET regions is below and vertically overlapping the first gate trench and a second of the first JFET regions is below and vertically overlapping the second gate trench, and first conductivity dopant concentrations of the respective first and second of the first JFET regions each exceed a first conductivity dopant concentration of the drift region, and the first and second of the first JFET regions are spaced apart from each other.

In some embodiments, the first and second gate trenches extend into an upper surface of the semiconductor layer structure.

In some embodiments, the semiconductor layer structure further comprises a trench shield having the second conductivity type that is in between a bottom of the first gate trench and the first of the first JFET regions. In some embodiments, an upper surface of the first of the first JFET regions is self-aligned with a lower surface of the trench shield.

In some embodiments, the first and second gate trenches are two of a plurality of gate trenches that extend into the upper surface of the semiconductor layer structure, the well region is one of a plurality of well regions in the semiconductor layer structure, and each of the plurality of first JFET regions is below a respective one of the gate trenches and spaced-apart from the other first JFET regions.

In some embodiments, the semiconductor layer structure further comprises a second JFET pattern that includes a plurality of spaced-apart second JFET regions having the first conductivity type, where each of the second JFET regions has a first conductivity dopant concentration that exceeds the first conductivity dopant concentration of the drift region, wherein each second JFET region is in between the drift region and a respective one of the well regions, and wherein an upper surface of each first JFET region is at a greater depth within the semiconductor layer structure than a lower surface of each second JFET region.

In some embodiments, the semiconductor layer structure further comprises a current spreading layer having the first conductivity type in between the drift region and the plurality of well regions, and the first conductivity dopant concentration of each of the first JFET regions exceeds a first conductivity dopant concentration of the current spreading layer, and the first conductivity dopant concentration of the current spreading layer exceeds the first conductivity dopant concentration of the drift region.

In some embodiments, an upper surface of the first of the first JFET regions is at a greater depth within the semiconductor layer structure than an upper surface of the current spreading layer.

In some embodiments, the semiconductor layer structure further comprises a first support shield and a second support shield that each have the second conductivity type and that each extend downwardly from the upper surface of the semiconductor layer structure into the drift region, where the first gate trench is in between the first support shield and the second support shield.

In some embodiments, the semiconductor layer structure further comprises a third JFET pattern that includes a plurality of third JFET regions having the first conductivity type, wherein a first of the third JFET regions is below and vertically overlaps the first support shield and a second of the third JFET regions is below and vertically overlaps the second support shield. In some embodiments, the first of the third JFET regions is spaced-apart from the second of the third JFET regions.

In some embodiments, the first support shield and the second support shield extend deeper into the semiconductor layer structure than the trench shield.

In some embodiments, an upper surface of the first of the first JFET regions is at a shallower depth in the semiconductor layer structure than upper surfaces of the first and second of the third JFET regions.

In some embodiments, the first of the third JFET regions extends along lower sidewalls of the first support shield.

In some embodiments, the first of the third JFET regions merges into the first of the first JFET regions.

In some embodiments, the first of the third JFET regions is below and vertically overlapping the first of the first JFET regions.

In some embodiments, the semiconductor layer structure further comprises a source region having the first conductivity type on the well region, a gate electrode that is at least partly in the first gate trench, and a gate dielectric layer that is at least partly in the first gate trench and is in between the gate electrode and the semiconductor layer structure.

Pursuant to further embodiments of the present invention, semiconductor devices are provided that comprise a semiconductor layer structure and a plurality of gate trenches extending into the semiconductor layer structure. The semiconductor layer structure comprises a drift region having a first conductivity type, at least one well region having a second conductivity type on the drift region, a plurality of trench shields having the second conductivity type positioned below the respective gate trenches, and a first JFET pattern having the first conductivity type, the first JFET pattern comprising a plurality of spaced-apart first JFET regions that are positioned below and vertically overlaps the respective trench shields. A first conductivity type dopant concentration of each first JFET region exceeds a first conductivity type dopant concentration of the drift region.

In some embodiments, each gate trench extends into an upper surface of the semiconductor layer structure.

In some embodiments, each first JFET region directly contacts a respective one of the trench shields.

In some embodiments, an upper surface of each first JFET region is self-aligned with a lower surface of a respective one of the trench shields.

In some embodiments, the semiconductor layer structure further comprises a second JFET pattern having the first conductivity type and a first conductivity dopant concentration that exceeds the first conductivity dopant concentration of the drift region, where the second JFET pattern comprises a plurality of second JFET regions, with each second JFET region in between the drift region and a respective one of the well regions. In some embodiments, an upper surface of each first JFET region is at a greater depth within the semiconductor layer structure than a lower surface of each second JFET region.

In some embodiments, the semiconductor layer structure further comprises a current spreading layer having the first conductivity type in an upper portion of the drift region, and a first conductivity dopant concentration of the first JFET pattern exceeds a first conductivity dopant concentration of the current spreading layer, and the first conductivity dopant concentration of the current spreading layer exceeds the first conductivity dopant concentration of the drift region.

In some embodiments, an upper surface of each first JFET region is at a greater depth within the semiconductor layer structure than an upper surface of the current spreading layer.

In some embodiments, the semiconductor layer structure further comprises a first support shield and a second support shield that each have the second conductivity type and that each extend downwardly from the upper surface of the semiconductor layer structure into the drift region, and wherein a first of the gate trenches is in between the first support shield and the second support shield.

In some embodiments, the semiconductor layer structure further comprises a third JFET pattern that includes a plurality of third JFET regions having the first conductivity type, wherein a first of the third JFET regions is positioned below and vertically overlaps the first support shield and a second of the third JFET regions is positioned below and vertically overlaps the second support shield and spaced apart from the first of the third JFET regions.

In some embodiments, the first support shield and the second support shield extend deeper into the semiconductor layer structure than each of the trench shields.

In some embodiments, upper surfaces of each first JFET region are at shallower depths in the semiconductor layer structure than upper surfaces of the third JFET regions.

In some embodiments, the first of the third JFET regions extends along lower sidewalls of the first support shield.

In some embodiments, the first of the third JFET regions merges into the first of the first JFET regions.

In some embodiments, the first of the third JFET regions is below and vertically overlapping the first of the first JFET regions.

Pursuant to further embodiments of the present invention, semiconductor devices are provided that comprise a semiconductor layer structure comprising a drift region having a first conductivity type, a current spreading layer having the first conductivity type and a first conductivity dopant concentration that exceeds a first conductivity dopant concentration of the drift region on the drift region, a well region having a second conductivity type above the current spreading layer, and a first JFET pattern having the first conductivity type that has a lower surface that extends deeper into the semiconductor layer structure than a lower surface of the current spreading layer, where the first JFET pattern includes a plurality of spaced apart first JFET regions, each of which has a first conductivity dopant concentration that exceeds a first conductivity dopant concentration of the current spreading layer. These semiconductor devices further comprise a gate trench extending into the semiconductor layer structure.

In some embodiments, the gate trench extends into an upper surface of the semiconductor layer structure.

In some embodiments, the semiconductor layer structure further comprises a trench shield having the second conductivity type that is in between a bottom of the gate trench and a first of the first JFET regions.

In some embodiments, an upper surface of the first of the first JFET regions is self-aligned with a lower surface of the trench shield.

In some embodiments, the gate trench is one of a plurality of gate trenches that extend into an upper surface of the semiconductor layer structure, the well region is one of a plurality of well regions in the semiconductor layer structure, and each of the first JFET regions is positioned below a respective one of the gate trenches and spaced-apart from the other first JFET regions.

In some embodiments, the semiconductor layer structure further comprises a second JFET pattern that includes a plurality of spaced-apart second JFET regions having the first conductivity type, wherein each of the second JFET regions has a first conductivity dopant concentration that exceeds the first conductivity dopant concentration of the drift region, wherein each second JFET region is in between the drift region and a respective one of the well regions, and wherein an upper surface of each first JFET region is at a greater depth within the semiconductor layer structure than a lower surface of each second JFET region.

In some embodiments, the semiconductor layer structure further comprises a first support shield and a second support shield that each have the second conductivity type and that each extend downwardly from the upper surface of the semiconductor layer structure into the drift region, where the gate trench is in between the first support shield and the second support shield.

In some embodiments, the semiconductor layer structure further comprises a third JFET pattern that includes a plurality of third JFET regions having the first conductivity type, wherein a first of the third JFET regions is positioned below the first support shield and a second of the third JFET regions is positioned below the second support shield.

In some embodiments, the first of the third JFET regions is spaced-apart from the second of the third JFET regions.

In some embodiments, the first support shield and the second support shield extend deeper into the semiconductor layer structure than the trench shield.

In some embodiments, upper surfaces of each first JFET region are at shallower depths in the semiconductor layer structure than upper surfaces of the first and second of the third JFET regions.

In some embodiments, the semiconductor layer structure further comprises a source region having the first conductivity type on the well region, a gate electrode that is at least partly in the gate trench, and a gate dielectric layer that is at least partly in the gate trench and is in between the gate electrode and the semiconductor layer structure.

Pursuant to additional aspects of the present invention, methods of forming a semiconductor device are provided in which a semiconductor layer structure is provided that has a drift region that has a first conductivity type. The semiconductor layer structure is etched to form a gate trench in the semiconductor layer structure. Second conductivity type dopants are implanted through a bottom of the gate trench to form a trench shield having a second conductivity type below the gate trench. First conductivity type dopants are implanted through the bottom of the gate trench to form a first JFET region having the first conductivity type below the gate trench.

In some embodiments, the trench shield is in between the gate trench and the first JFET region.

In some embodiments, a same ion implantation mask is used to implant the second conductivity type dopants through the bottom of the gate trench to form the trench shield and to implant the first conductivity type dopants through the bottom of the gate trench to form the first JFET region.

In some embodiments, the first JFET region has a higher first conductivity type dopant concentration than the drift region.

In some embodiments, a channeled implant is used to implant the first conductivity type dopants through the bottom of the gate trench to form the first JFET region.

In some embodiments, an upper surface of the first JFET region is self-aligned with a lower surface of the trench shield.

In some embodiments, etching the semiconductor layer structure to form the gate trench in the semiconductor layer structure comprises etching the semiconductor layer structure to form a plurality of gate trenches in the semiconductor layer structure, wherein implanting second conductivity type dopants through the bottom of the gate trench to form the trench shield having the second conductivity type below the gate trench comprises implanting second conductivity type dopants through bottoms of the gate trenches to form a plurality of trench shields having a second conductivity type below the respective gate trenches, and wherein implanting first conductivity type dopants through the bottom of the gate trench to form the first JFET region having the first conductivity type below the gate trench comprises implanting first conductivity type dopants through the bottoms of the respective gate trenches to form a plurality of first JFET regions having the first conductivity type below the respective gate trenches, where the plurality of first JFET regions comprise a first JFET pattern.

In some embodiments, the first JFET regions are spaced-apart from one another.

In some embodiments, the method further comprises forming a second JFET pattern that includes a plurality of spaced-apart second JFET regions having the first conductivity type, wherein each of the second JFET regions has a first conductivity dopant concentration that exceeds the first conductivity dopant concentration of the drift region.

In some embodiments, the method further comprises forming a plurality of well regions having the second conductivity type on the drift region, wherein each second JFET region is in between the drift region and a respective one of the well regions, and wherein an upper surface of each first JFET region is at a greater depth within the semiconductor layer structure than a lower surface of each second JFET region.

In some embodiments, the method further comprises forming a current spreading layer having the first conductivity type in an upper portion of the drift region, where the first conductivity dopant concentration of the first JFET region exceeds a first conductivity dopant concentration of the current spreading layer, and the first conductivity dopant concentration of the current spreading layer exceeds the first conductivity dopant concentration of the drift region.

In some embodiments, an upper surface of the first JFET region is at a greater depth within the semiconductor layer structure than an upper surface of the current spreading layer.

In some embodiments, the method further comprises implanting second conductivity type dopants using a first ion implantation mask to form a first support shield and a second support shield that each have the second conductivity type in the semiconductor layer structure, where the first and second support shields each extend downwardly from the upper surface of the semiconductor layer structure into the drift region, and the gate trench is in between the first support shield and the second support shield.

In some embodiments, the method further comprises implanting first conductivity type dopants into the semiconductor layer structure to form a third JFET pattern that includes a plurality of third JFET regions having the first conductivity type in the semiconductor layer structure, wherein a first of the third JFET regions is below and vertically overlapping the first support shield and a second of the third JFET regions is below and vertically overlapping the second support shield.

In some embodiments, the first ion implantation mask is used in forming the first and second support shields and the third JFET pattern.

In some embodiments, the first of the third JFET regions is spaced-apart from the second of the third JFET regions.

In some embodiments, the first support shield and the second support shield extend deeper into the semiconductor layer structure than the trench shield.

In some embodiments, an upper surface of the first JFET region is at a shallower depth in the semiconductor layer structure than upper surfaces of the first and second of the third JFET regions.

Pursuant to additional embodiments of the present invention, methods of forming a semiconductor device are provided in which a semiconductor layer structure is provided that has a drift region that has a first conductivity type. The semiconductor layer structure is etched to form a gate trench in the semiconductor layer structure. A first ion implantation mask is used to implant dopants having a second conductivity type into the semiconductor layer structure to form a plurality of support shields having the second conductivity type in the semiconductor layer structure. The first ion implantation mask is also used to implant dopants having the first conductivity type into the semiconductor layer structure to form a third JFET pattern in the semiconductor layer structure.

In some embodiments, the third JFET pattern includes a plurality of spaced-apart third JFET regions that are positioned below the respective support shields.

In some embodiments, an upper surface of each of the third JFET regions is self-aligned with a lower surface of a respective one of the support shields.

In some embodiments, the method further comprises implanting second conductivity type dopants through a bottom of the gate trench to form a trench shield having a second conductivity type below the gate trench and implanting first conductivity type dopants through the bottom of the gate trench to form a first JFET region having the first conductivity type below the gate trench.

In some embodiments, the trench shield is in between the gate trench and the first JFET region.

In some embodiments, a second ion implantation mask is used to implant second conductivity type dopants through the bottom of the gate trench to form the trench shield and to implant first conductivity type dopants through the bottom of the gate trench to form the first JFET region.

In some embodiments, the first JFET region has a higher first conductivity type dopant concentration than the drift region and a lower first conductivity type dopant concentration than the third JFET pattern.

In some embodiments, an upper surface of the first JFET region is self-aligned with a lower surface of the trench shield.

Pursuant to other embodiments of the present invention, semiconductor devices are provided that comprise a semiconductor layer structure comprising a drift region having a first conductivity type, a well region having a second conductivity type on the drift region, a first support shield having the second conductivity type, and a third junction field effect (“JFET”) region having the first conductivity type, a first conductivity dopant concentration of the third JFET region exceeding a first conductivity dopant concentration of the drift region and a first gate trench and a second gate trench that each extend into the semiconductor layer structure. The first support shield is in between the first and second gate trenches, and the third JFET region is below and vertically overlapping the first support shield.

In some embodiments, the semiconductor device further comprises a third gate trench extending into the semiconductor layer structure, and the semiconductor layer structure further comprises a second support shield having the second conductivity type that is in between the second and third gate trenches and an additional third JFET region having the second conductivity type and a first conductivity dopant concentration exceeding a first conductivity dopant concentration of the drift region that is positioned below the second support shield, where the third JFET region and the additional third JFET region are spaced apart from each other.

In some embodiments, the third JFET region and the additional third JFET region are part of a third JFET pattern that is formed within the drift region.

In some embodiments, the third JFET pattern is deeper in the semiconductor layer structure than a first trench shield having the second conductivity type that is positioned below the first gate trench and a second trench shield having the second conductivity type that is positioned below the second gate trench.

In some embodiments, the semiconductor layer structure further comprises a first JFET pattern that includes a plurality of spaced-apart first JFET regions, where a first of the first JFET regions is positioned below and vertically overlaps the first trench shield and a second of the first JFET regions is positioned below and vertically overlaps the second trench shield.

In some embodiments, an upper surface of the first of the first JFET regions is at a shallower depth in the semiconductor layer structure than upper surfaces of the third JFET region.

In some embodiments, an upper surface of the third JFET region is self-aligned with a lower surface of the first support shield.

In some embodiments, the third JFET region is a first of a plurality of spaced-apart third JFET regions, and the first and second support shields are two of a plurality of support shields, and wherein each third JFET region is positioned below and vertically overlaps a respective one of the support shields.

Pursuant to still further embodiments of the present invention, semiconductor device are provided that comprise a semiconductor layer structure comprising a drift region having a first conductivity type, a well region having a second conductivity type on an upper surface of the drift region, a first support shield having the second conductivity type, and a third junction field effect (“JFET”) region having the first conductivity type and extending below an upper surface of the drift region, a first conductivity dopant concentration of the third JFET region exceeding a first conductivity dopant concentration of the drift region and a first gate trench and a second gate trench that each extend into the semiconductor layer structure. The first support shield is in between the first and second gate trenches, and the third JFET region directly contacts sidewalls of the first support shield.

In some embodiments, the third JFET region is also below and vertically overlapping the support shield.

In some embodiments, the third JFET region does not directly contact sidewalls of the first gate trench.

In some embodiments, the semiconductor layer structure further comprises a trench shield having the second conductivity type below and vertically overlapping the first gate trench.

In some embodiments, the semiconductor layer structure further comprises a first JFET region having the first conductivity type below and vertically overlapping the trench shield, where a first conductivity dopant concentration of the first JFET region exceeds a first conductivity dopant concentration of the drift region.

### BRIEF DESCRIPTION OF THE DRAWINGS

FIG. 1 is a semi-log graph illustrating the lifetime of a gate oxide layer as a function of applied electric field strength.

FIG. 2 is a schematic cross-sectional view of a unit cell of a gate trench power MOSFET having support shields.

FIG. 3A is a schematic top view of a gate trench silicon carbide power MOSFET according to certain embodiments of the present invention.

FIG. 3B is a schematic top view of the gate trench silicon carbide power MOSFET of FIG. 3A with various of the upper metal and dielectric layers removed.

FIG. 3C is a schematic top view of the portion of the gate trench silicon carbide power MOSFET of FIG. 3B shown in the box labelled A in FIG. 3B.

FIGS. 3D and 3E are schematic cross-sectional views of the gate trench silicon carbide power MOSFET of FIGS. 3A-3B that are taken along lines 3D-3D and 3E-3E, respectively, of FIG. 3C.

FIG. 3F is a schematic top view of the portion of a modified version of the gate trench silicon carbide power MOSFET of FIGS. 3A-3E, where the view corresponds to the portion of the MOSFET shown in the box labelled A in FIG. 3B.

FIGS. 4A-4G are schematic cross-sectional views illustrating a method of fabricating the gate trench silicon carbide power MOSFET of FIGS. 3A-3E.

FIGS. 5A and 5B are flow charts illustrating methods of fabricating gate trench silicon carbide power MOSFETs according to embodiments of the present invention.

FIGS. 6A-6C are schematic cross-sectional views of modified versions of the gate trench silicon carbide power MOSFET of FIGS. 3A-3E where the cross-sections are taken along line 3D-3D of FIG. 3C.

FIGS. 7A-7D are schematic cross-sectional views of gate trench silicon carbide power MOSFETs according to further embodiments of the present invention.

FIGS. 8A-8D are schematic cross-sectional views of gate trench silicon carbide power MOSFETs according to still further embodiments of the present invention.

FIGS. 9A-9D are schematic cross-sectional views of gate trench silicon carbide power MOSFETs according to yet additional embodiments of the present invention.

FIGS. 10A-10C are schematic cross-sectional views of gate trench silicon carbide power MOSFETs according to still further embodiments of the present invention.

FIGS. 11A-11B are schematic cross-sectional views of gate trench silicon carbide power MOSFETs according to yet further embodiments of the present invention

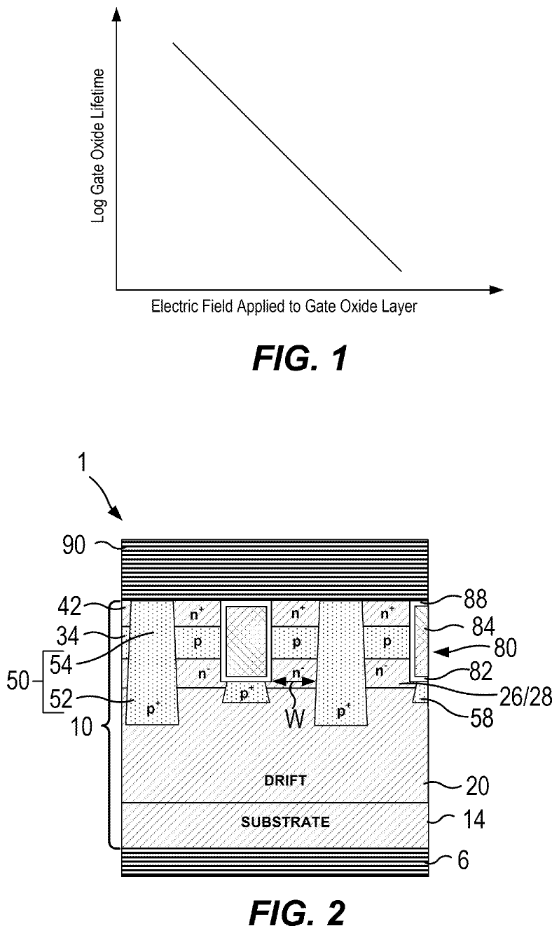

### DETAILED DESCRIPTION

Vertical silicon carbide based power semiconductor devices that have gate trenches such as vertical power MOSFETs and IGBTs are attractive for many applications due to their inherent lower specific on-resistance, which may result in more efficient operation for power switching operations. The channels in a gate trench vertical power device are formed in the sidewalls of the gate trenches, and hence are vertical channels. The carrier mobility in these vertically-oriented sidewall channels may be about 2-4 times higher than the corresponding carrier mobility in the horizontal channel of a standard planar gate (i.e., non-gate trench) vertical power device. The higher carrier mobility provided by the vertically-oriented sidewall channels results in increased current density during on-state operation allowing for higher switching speeds. The gate trench design also reduces the overall pitch of the device, which increases device integration. The lower conduction losses (due to the reduced on-state resistance) and improved switching speeds make gate trench power devices particularly well-suited for high frequency power applications having low to moderate voltage blocking requirements (e.g., 600-1200 Volts). These devices may have reduced requirements for associated passive components and require relatively simple cooling schemes. As MOSFETs are the most widely used silicon carbide based gate trench power semiconductor devices, the discussion below focuses on MOSFET embodiments. It will be appreciated, however, that each of the described embodiments may alternatively be implemented using non-oxide gate dielectric layers (e.g., nitrides, high dielectric constant materials, etc.), and that the same techniques may be used to form other gate trench power semiconductor devices such as IGBTs, gate-controlled thyristors and the like.

As discussed above, gate trench power MOSFETs are susceptible to oxide reliability issues due to the presence of high electric fields in the gate oxide layers that line the bottoms and sidewalls of the gate trenches during reverse blocking operation. The high electric fields degrade the gate oxide layer over time, and may eventually result in failure of the device. When gate trench MOSFETs operate in reverse blocking operation (i.e., when the MOSFET is in its off-state), the source terminal of the MOSFET is typically grounded, the gate terminal is typically grounded or at a negative bias voltage, and the drain terminal is typically at a high positive voltage. During such reverse blocking operations, high electric fields extend upwardly from the drain terminal (which is on the bottom surface of the semiconductor layer structure) toward the top surface of the semiconductor layer structure. Thus, under reverse blocking operation, the bottom portion of the gate dielectric layer experiences the highest electric field levels. Due to electric field crowding effects, the electric field levels in the lower “corners” of the gate oxide layer at the bottom edges of the gate trench may be particularly high (i.e., the portions of the gate oxide layers that cover the region where the sidewalls of the gate trenches merge into the bottom of the gate trenches). Moreover, due to the difference in permittivity between silicon carbide and silicon oxide, the electric field in a silicon oxide gate oxide layer may be about 2.6 times higher than the electric field in the silicon carbide semiconductor layer structure adjacent the gate oxide layer. Breakdown of the silicon oxide occurs when the electric field reaches a critical level. In order to avoid such breakdown, power MOSFETs may be operated with the drain voltage at lower levels during reverse blocking operation to ensure that the electrical field does not reach a level that will result in breakdown. In other words, the voltage rating of a power MOSFET may be set to ensure that premature gate oxide breakdown will not occur.

So-called “trench shields” (also called “bottom shields”) are often provided underneath the gate trenches of gate trench power MOSFETs in order to reduce the electric field levels in the gate oxide layer during reverse blocking operation. These trench shields are formed by doping the portions of the semiconductor layer structure underneath the gate trenches with dopants having the same conductivity type as the dopants included in the channel regions of the device. The trench shields are typically formed via one or more ion implantation processes in which p-type dopant ions (for an n-type MOSFET) are implanted through the bottom surfaces of the gate trenches. The trench shields may, for example, extend downwardly 0.5 to 1.0 microns or more from the bottoms of the gate trenches into the semiconductor layer structure of the device, and may be moderately to highly doped regions. The trench shields are electrically connected to the source terminal of the MOSFET by p-type trench shield connection patterns. These trench shield connection patterns may be in and/or outside the active region of the device.

Gate trench power MOSFETs may also include additional shielding regions that are referred to as “support shields.” The support shields are formed in the semiconductor layer structure between adjacent gate trenches and, like the trench shields, may comprise moderately or highly doped semiconductor regions having the same conductivity type as the channel regions of the MOSFET. The support shields may be formed by a high-energy ion implantation process. The support shields may directly connect to the source metallization in the active region of the device. An upper portion of each support shield may be more highly doped than a lower portion of the support shield to provide a support shield contact section that forms a low resistivity connection with the source metallization layer. It will be appreciated that, as used herein, references to the “depth” of structures or elements within a semiconductor layer structure refer to the distance that the lowermost surfaces of the structures or elements are from the upper surface of the semiconductor layer structure, where the upper surface of the semiconductor layer structure is the surface opposite the substrate and is also the surface in which the gate trenches are formed.

FIG. 2 is a schematic cross-sectional view of a small portion of a silicon carbide power MOSFET 1 that includes support shields. The cross-section of FIG. 2 shows one full unit cell of the MOSFET 1 and portions of two adjacent unit cells. As shown in FIG. 2, the MOSFET 1 includes a heavily-doped n-type (n+) silicon carbide semiconductor substrate 14. A lightly-doped n-type (n−) silicon carbide drift region 20 is provided on the upper surface of the substrate 10. An n-type silicon carbide JFET pattern 26 that includes a plurality of spaced apart individual JFET regions 28 is formed on the drift region 20. The JFET regions 28 may be more heavily doped than the drift region 20. Moderately-doped (p) silicon carbide p-type wells 34 (also referred to as “p-wells”) are provided on the upper surface of the n-type JFET pattern 26. Heavily-doped (n+) n-type silicon carbide source regions 42 are formed on the p-wells 34. The substrate 14, drift region 20, JFET regions 28, p-wells 34 and source regions 42 are part of a semiconductor layer structure 10 of the MOSFET 1.

The semiconductor layer structure 10 further includes p-type support shields 50 that extend downwardly from an upper portion (e.g., the upper surface) of the semiconductor layer structure 10. Lower portions 52 of the p-type support shields 50 may be moderately (p) doped silicon carbide regions and upper portions 54 of the p-type support shields 50 may be heavily doped (p+) silicon carbide regions. As is further shown in FIG. 2, plurality of gate trenches 80 are formed in the upper portion of the semiconductor layer structure 10. The semiconductor layer structure 10 also includes p-type trench shields 58 that are formed underneath the respective gate trenches 80, typically by implanting p-type dopants through the bottoms of the gate trenches 80. The p-type trench shields 58 extend underneath the respective gate trenches 80 for all or substantially all of the length of the gate trench 80 and may be moderately (p) or heavily doped (p+) silicon carbide regions. The p-type support shields 50 and the p-type trench shields 58 act to reduce the electric field levels that form in gate oxide layers (discussed below) during reverse blocking operation.

A gate oxide layer 82 is formed conformally within each gate trench 80, and gate electrodes 84 are formed in the gate trenches 80 on the gate oxide layers 82. An intermetal dielectric pattern 88 covers the gate electrodes 84. A source metallization layer 90 is formed on the intermetal dielectric pattern 88 and on the heavily-doped n-type source regions 42 and upper portions 54 of the support shields 50. A drain contact 6 is formed on the lower surface of the substrate 14.

As shown, the p-type support shields 50 may extend downwardly part or all of the way through the JFET pattern 26. Likewise, the gate trenches 80 and the p-type trench shields 56 thereunder also extend downwardly part or all of the way through the JFET pattern 26. The minimum lateral width W of each JFET region 28 is referred to as the JFET gap. Since during on-state operation the source-to-drain current flows through these JFET gaps, the width W of each JFET gap has a direct impact on the on-state resistance of MOSFET 1.

Pursuant to embodiments of the present invention, vertical gate trench silicon carbide power MOSFETs (and other power semiconductor devices) are provided that have one or more deep JFET patterns. Each of these JFET patterns may comprise a plurality of spaced-apart JFET regions. Each of the JFET regions that form these JFET patterns may comprise regions in the semiconductor layer structure that are implanted with dopants having the same conductivity type as the drift region of the device, and which have a higher doping concentration than the drift region. In some embodiments, the power MOSFETs may include a first JFET pattern which comprises first JFET regions that are positioned underneath the respective trench shields so that each trench shield may be in between a respective one of the gate trenches and a respective one of the first JFET regions. These power MOSFETs may optionally include a second JFET pattern that includes a plurality of first JFET regions that are positioned in between the well regions of the MOSFET (which include the channel regions) and the drift region. The power MOSFETs may additionally or alternatively include a third JFET pattern which comprises third JFET regions that are positioned underneath and vertically overlapping the respective support shields. The power MOSFETs according to embodiments of the present invention may include one, two or all three of the first, second and third JFET patterns, and may also optionally include a current spreading layer between the drift region and the well regions.

The power semiconductor devices according to embodiments of the present invention include features that may help reduce the negative impact that shield regions such as the above-discussed trench shields and support shields may have on the on-state resistance of a power semiconductor device. As discussed above, the trench shields and supports shields are included in various power semiconductor devices in order to help protect the gate oxide layers that line the gate trenches from high electric field values during reverse blocking operation, as these high electric fields can damage the gate oxide layer over time. While including trench shields and support shields in a power MOSFET may improve the reliability (e.g., average time to failure) of the MOSFET, they tend to funnel the on-state currents which increases the on-state resistance. By providing JFET patterns underneath the trench shields and/or support shields, larger portions of the on-state currents may be directed toward the regions underneath the trench shields and the support shields, thereby counteracting the natural tendency of the trench shields and support shields to funnel the on-state current, so that the current is more evenly spread throughout the drift region of the power MOSFET, which lowers the on-state resistance. While the JFET regions, since they are more heavily doped than the drift region, may tend to increase the electric field levels in the drift region, the trench shields and support shields may mostly counteract this increase so that the improvement in on-state resistance is more significant than any increase in the electric field values in the gate oxide layer and associated degradation to device reliability.

In some embodiments, the above-described first and third JFET patterns may be formed via ion implantation without the need for any additional masking steps. For example, the first JFET pattern may be formed via ion implantation using the same ion implantation mask that is used to form the trench shields, and the third JFET pattern may be formed via ion implantation using the same ion implantation mask that is used to form the support shields. As a result, the first JFET regions of the first JFET pattern may be self-aligned with the trench shields, and the third JFET regions of the third JFET pattern may be self-aligned with the support shields.

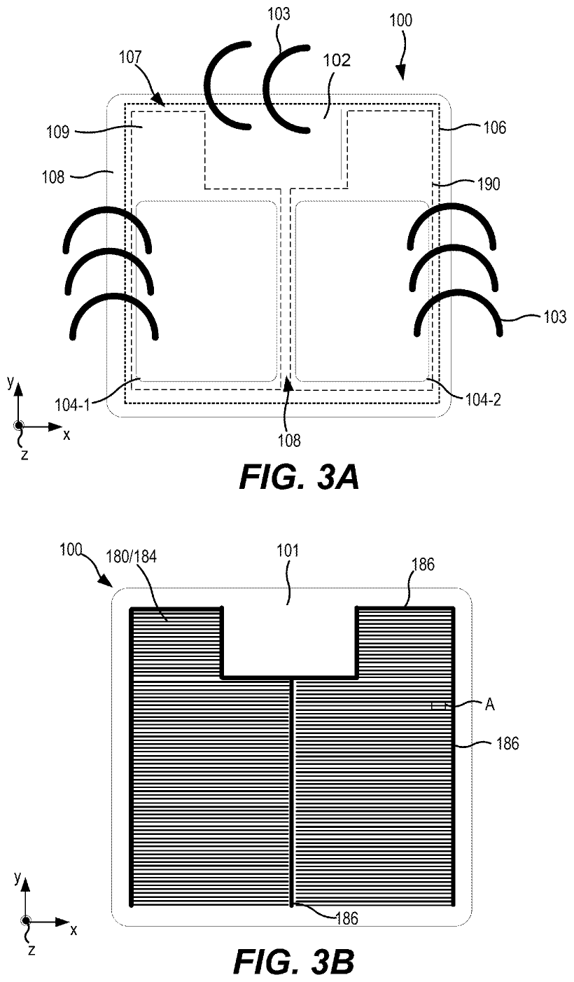

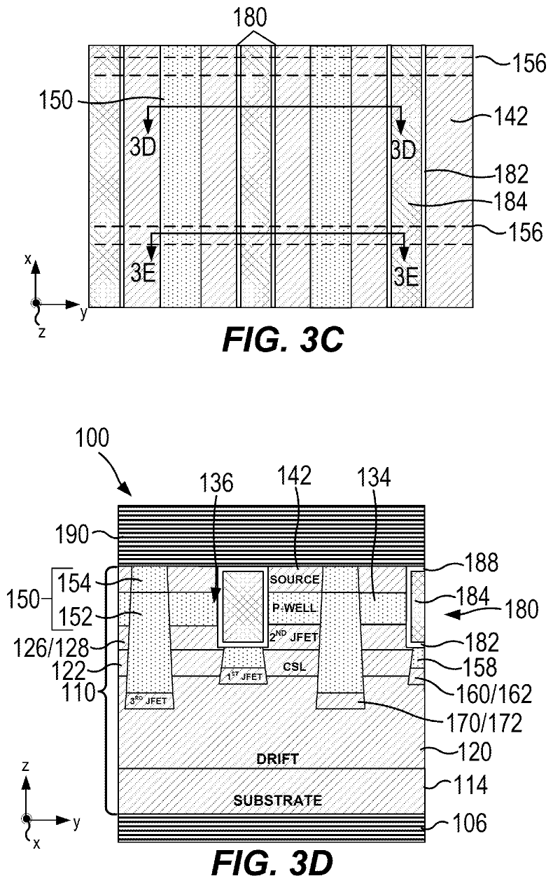

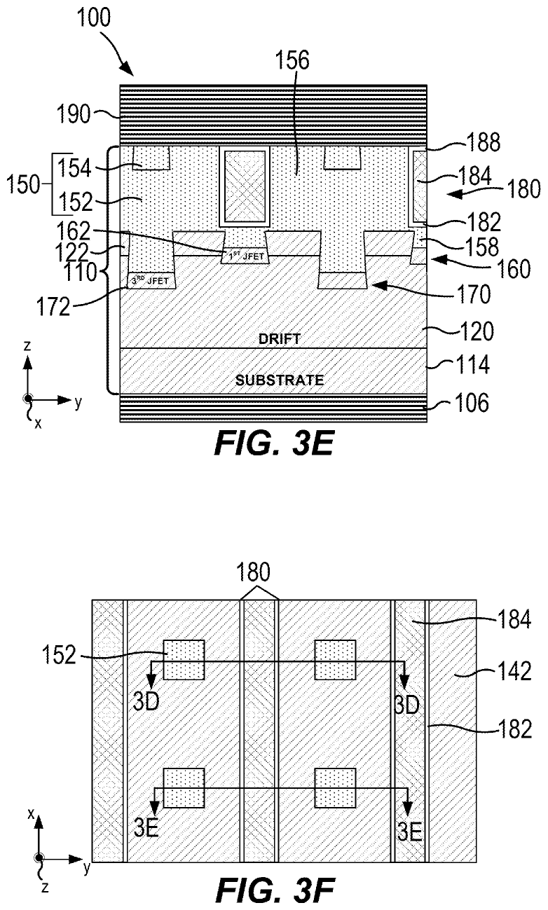

Embodiments of the present invention will now be described in more detail with reference to FIGS. 3A-11. It will be appreciated that features of the different embodiments disclosed herein may be combined in any way to provide many additional embodiments. Thus, it will be appreciated that various features of the present invention are described below with respect to specific examples, but that these features may be added to other embodiments and/or used in place of example features of other embodiments to provide many additional embodiments. Thus, the present invention should be understood to encompass these different combinations. Additionally, while the example embodiments focus on MOSFET implementations, it will be appreciated that the same techniques may be used in other gate trench power semiconductor devices such as insulated gate bipolar transistors (IGBTs), gate controlled thyristors and the like.

FIG. 3A is a schematic top view of a gate trench silicon carbide power MOSFET 100 according to certain embodiments of the present invention. FIG. 3B is a schematic plan view of the power MOSFET 100 with various top-side metal and dielectric layers thereof omitted to show the gate electrodes and gate buses. FIG. 3C is a schematic top view of the portion of the gate trench silicon carbide power MOSFET 100 of FIG. 3B shown in the box labelled A in FIG. 3B. FIGS. 3D-3E are schematic cross-sectional views of about two unit cells of the gate trench silicon carbide power MOSFET 100 that is taken along lines 3D-3D and 3E-3E, respectively, of FIG. 3C. It will be appreciated that the thicknesses of various of the layers and regions in FIGS. 3A-3E are not necessarily drawn to scale. The same is true with respect to the other figures included in this application.

The power MOSFET 100 includes a semiconductor layer structure 110 (see FIG. 3D) that comprises one or more semiconductor substrates and/or layers. At least one of the semiconductor layers in the semiconductor layer structure 110 may be a silicon carbide layer. Various metal and/or dielectric layers are formed on either side of the semiconductor layer structure 110 and embedded in the semiconductor layer structure 110.

As shown in FIG. 3A, the top-side metal layers include a gate bond pad 102 and one or more source bond pads 104-1, 104-2 that are formed on the upper side of the semiconductor layer structure 110. A metal drain pad 106 (shown as a dotted box in FIG. 3A) is provided on the bottom side of the semiconductor layer structure 110. The gate bond pad 102, the source bond pads 104 and the drain pad 106 form the respective gate, source and drain terminals of power MOSFET 100. The gate and source pads 102, 104 may each be formed of a metal, such as aluminum, that bond wires can be readily attached to via conventional techniques such as thermo-compression or soldering. The drain pad 106 may likewise be a metal pad. A protective layer 109 such as a polyimide layer may cover the entire upper surface of power MOSFET 100 except for the gate and source pads 102, 104.

Still referring to FIG. 3A, the power MOSFET 100 includes a source metallization layer 190 (indicated by the dashed boxes in FIG. 3A) that electrically connects certain regions of the semiconductor layer structure 110 to the source bond pads 104-1, 104-2. The source bond pads 104-1, 104-2 may be portions of the source metallization layer 190 that are exposed through openings in the protective layer 109 or may be separate metal layers. The source metallization layer 190 may generally overlie or correspond to an “active region” 107 of the power MOSFET 100 where the unit cell transistors are located. An inactive region 108 of power MOSFET 100 surrounds the active region 107. The inactive region 108 may include a termination region that extends around the periphery of the MOSFET 100 that includes guard rings, junction termination elements or other termination structures (not shown), a gate pad region that underlies the gate pad 102, and gate bus regions (discussed below).

Bond wires 103 are shown in FIG. 3A that may be used to connect the gate bond pad 102 and the source bond pads 104 to external circuits or the like. The drain pad 106 on the bottom side of power MOSFET 100 may be connected to an external circuit through, for example, an underlying submount (not shown).

FIG. 3B is another plan view of power MOSFET 100 with the gate and source bond pads 102, 104, the polymide layer 109, the source metallization layer 190, the intermetal dielectric layers 188 and various other metal and dielectric layers removed to show the gate electrodes 184 that are formed in gate trenches 180 in the semiconductor layer structure 110. A patterned field oxide layer (not shown) is formed on the semiconductor layer structure 110 in the inactive region 108 of the MOSFET 100. The field oxide layer may be a relatively thick oxide layer (e.g., ten to twenty times thicker than the gate oxide layers that are discussed below). A polysilicon layer 101 may be formed on the field oxide layer and may be formed in the region where the gate bond pad 102 is formed so that the gate bond pad 102 vertically overlaps the field oxide layer and the polysilicon layer 101. As used herein, two elements of a semiconductor device are considered to “vertically overlap” if an axis that is perpendicular to the major surfaces of a semiconductor layer structure of the semiconductor device intersects both elements.

One or more gate buses 186 are provided that extend around the periphery of the active region 107. The field oxide layer also typically runs underneath each gate bus 186. The gate buses 186 are electrically connected to the gate bond pad 102, often through gate resistors (not shown). A plurality of gate trenches 180 (see FIGS. 3D-3E) are formed throughout the active region 107. A gate electrode 184 is formed in each gate trench 180. In the depicted power MOSFET 100, the gate electrodes 184 extend horizontally across the semiconductor layer structure 110. In other cases, the gate electrodes 184 may extend vertically across the semiconductor layer structure 110, or both horizontally-extending and vertically-extending gate electrodes 184 can be provided to form a grid-like gate electrode structure. The gate electrodes 184 may alternatively comprise closed rings in embodiments in which the semiconductor device has a cell configuration. The gate electrodes 184 may be connected to the gate pad 102 through the gate buses 186. The gate electrodes 184 may comprise, for example, a doped polysilicon pattern. The gate buses 186 may comprise polysilicon and/or metal structures in example embodiments and typically are in the inactive region 108 of power MOSFET 100.

FIG. 3C is a schematic top view of the portion of the gate trench silicon carbide power MOSFET 100 of FIG. 3B shown in the box labelled A. In FIG. 3C, various dielectric and metal layers are omitted so that the upper surface of the semiconductor layer structure 110 is visible. As shown in FIG. 3C, the longitudinal axes of each gate trench 180 extends in the x-direction so that the gate trenches 180 extend in parallel to each other. The gate trenches 180 extend downwardly into the upper surface of the semiconductor layer structure 110. Heavily-doped n-type source regions 142 are formed in the upper surface of the semiconductor layer structure 110 in between the gate trenches 180. The source regions 142 extend longitudinally in the x-direction. Moderately and/or heavily doped p-type support shields 150 are formed as longitudinally-extending stripes within each n-type source region 154.

FIG. 3D is a schematic cross-sectional view taken along line 3D-3D of FIG. 3C that illustrates almost two unit cells of the power MOSFET 100. As shown in FIG. 3D, the power MOSFET 100 includes an n-type silicon carbide semiconductor substrate 114. The substrate 114 may comprise, for example, a single crystal 4H silicon carbide semiconductor substrate that is heavily-doped with n-type impurities (i.e., an n+ silicon carbide substrate). The impurities may comprise, for example, nitrogen or phosphorous. In example embodiments, the n-type substrate 114 may have a doping concentration of, for example, between 1×101⁸ atoms/cm³ and 1×10²¹ atoms/cm³, although other doping concentrations may be used. The substrate 114 may be relatively thick in some embodiments (e.g., 20-100 microns or more). It should be noted that while the substrate 114 is depicted as a relatively thin layer, this is done to allow enlarging the thickness of other layers and regions in FIG. 3D, and it will be appreciated that the substrate 114 will typically be much thicker than shown. The thickness of various other layers of power MOSFET 100 likewise may not be shown to scale in order to allow other portions of the devices to be enlarged in the figures.

A lightly-doped n-type (n−) silicon carbide drift layer 120 (which also may be referred to herein as a drift region 120) is provided on an upper surface of the substrate 114. Typically, the drift layer 120 is formed via an epitaxial growth process and is doped during growth. The n-type drift region 120 may have, for example, a doping concentration of 5×10¹⁵ to 5×10¹⁷ dopants/cm³. For MOSFETs having a reverse blocking voltage rating of between 600-1200 volts, a doping concentration of 5×10¹⁵ to 5×10¹⁶ dopants/cm³ may be used in example embodiments. The n-type drift region 120 may be a thick region, having a vertical height above the substrate 114 of, for example, 3-50 microns, and can be doped during growth.

An n-type current spreading layer (CSL) 122 is provided on an upper surface of the n-type drift layer 120. The n-type current spreading layer 122 may have a higher n-type dopant concentration than the n-type drift region 120. For example, n-type current spreading layer 122 may have a doping concentration of 1×10¹⁶ to 8×10¹⁷ dopants/cm³. For MOSFETs having a reverse blocking voltage rating of between 600-1200 volts, a doping concentration of 1×10¹⁶ to 1×10¹⁷ dopants/cm³ may be used in example embodiments. In example embodiments, the doping concentration of the type current spreading layer 122 may be between 1.5 times and five times higher than the n-type doping concentration of the drift region 120 or between 1.5 times and 2.5 times higher than the n-type doping concentration of the drift region 120. The current spreading layer 122 may be grown by epitaxial growth or formed by ion implantation.

A second n-type JFET pattern 126 (the MOSFET 100 also includes a first JFET pattern 160, which is described below) that includes one or more second JFET regions 128 is provided on an upper surface of the current spreading layer 122. As shown, typically the second JFET pattern 126 will include a plurality of spaced-apart second JFET regions 128. Each second JFET region 128 may have, for example, an n-type doping concentration that exceeds a doping concentration of the drift region 120. The n-type doping concentration of each second JFET region 128 may also exceed the doping concentration of the current spreading layer 122. In example embodiments, the n-type doping concentration of each second JFET region 128 may be between 5×10¹⁶ and 1×10¹⁸ dopants/cm³. For MOSFETs having a reverse blocking voltage rating of between 600-1200 volts, a doping concentration of 2×10¹⁶ to 2×10¹⁷ dopants/cm³ may be used in example embodiments. The doping concentration of each second JFET region may be at least twice the doping concentration of the drift layer 120 in example embodiments (e.g., 2-4 times the doping concentration of the drift layer 120 or 2-3 times the doping concentration of the drift layer 120). The second JFET regions 128 are shown as extending slightly below the gate trenches 180 (i.e., the second JFET regions 128 extend deeper into the semiconductor layer structure 110 than the gate trenches 180). In other embodiments the gate trenches 180 may extend deeper into the semiconductor layer structure 110 than the second JFET regions 128. This is true in all embodiments disclosed herein.

The drift layer 120 and the substrate 114 together act as a common drain region for the power MOSFET 100. The drain pad 106 is formed on the substrate 114 opposite the drift region 120.

Still referring to FIG. 3D, a plurality of moderately-doped (p) p-type silicon carbide well regions 134 (also referred to herein as p-wells 134) are provided on the upper surfaces of the respective second JFET regions 128. Each p-well 134 may be a moderately-doped (p) p-type region. The p-wells 134 are typically formed by ion implantation. In example embodiments, the p-wells 134 may have a p-type dopant concentration of, for example, between 5×10¹⁶ to 1×10¹⁸ atoms/cm³.

A plurality of heavily-doped (n+) n-type silicon carbide source regions 142 are provided on upper surfaces of the respective p-wells 134. The source regions 142 may be formed by ion implantation. Each source region 142 may have a doping concentration of, for example, between 1×10¹⁹ atoms/cm³ and 5×10²¹ atoms/cm³.

As is further shown in FIG. 3D, p-type support shields 150 are provided that extend downwardly from the upper portion (e.g., the upper surface) of the semiconductor layer structure 110 into the silicon carbide drift region 120. Each p-type support shield 150 may include a moderately doped (p) lower portion 152 and a heavily doped (p+) upper portion 154. For example, the lower portion 152 of each p-type support shield 150 may have a doping concentration between about 5×10¹⁶ and 1×10¹⁹, while the upper portion 154 of each p-type support shield 150 may have a doping concentration between about 1×10¹⁹ and 1×10²¹. The highly doped upper portions 154 of the support shields 150 provide a low resistance connection between the source metallization layer 190 and the p-wells 134 and the lower portions 152 of the support shields 150. In example embodiments, each p-type support shield 150 may extend to a depth of between 0.1 microns and 4.0 microns from the upper surface of the semiconductor layer structure 160. In certain embodiments, the depth of each p-type support shield 150 may be between 1.0 and 3.0 microns, between 1.0 and 2.5 microns, between 1.5 and 3.0 microns, between 1.5 and 2.5 microns, or between 0.5 and 2.5 microns. The p-type support shields 150 may act to reduce the electric field levels that form in gate oxide layers during device reverse blocking operation.

As shown in FIG. 3D, a lateral width of each support shield 150 may increase as the support shield 150 extends further into the semiconductor layer structure 110. Herein, the width of a support shield in a gate trench MOSFET or other power semiconductor device having a stripe configuration refers to the extent of the support shield in the y-direction of FIG. 3D (i.e., in a direction that is parallel to a major surface of the semiconductor layer structure and perpendicular to the sidewalls of the gate trenches). The lateral width of each support shield 150 may increase with increasing depth because the support shields 150 are formed using standard ion implantation techniques where the dopant ions are implanted at high energy at an angle of 90° into the upper surface of the semiconductor layer structure 110. As the dopant ions pass through the semiconductor material, they collide with atoms in the crystal lattice, which may redirect the dopant ions in different directions so that at least some of the dopant ions will move both vertically and laterally through the crystal lattice. The farther a dopant ion is implanted into the semiconductor layer structure 110, the more likely that the dopant ion includes some degree of lateral movement. This lateral movement results in the implanted region spreading out laterally with increased depth, which is often referred to as “blooming.”

As discussed above, a plurality of gate trenches 180 are formed in the upper surface of the semiconductor layer structure 110. P-type trench shields 158 are formed underneath the respective gate trenches 180 and may extend underneath the respective gate trenches 180 for all or substantially all of the length of the gate trench 180. The p-type trench shields 158 may be moderately or heavily doped (p+) silicon carbide regions. For example, each p-type trench shields 158 may have a doping concentration between about 1×10¹⁷ and 1×10²¹. In other embodiments, each p-type trench shield 158 may have a doping concentration between about 1×10¹⁸ and 1×10²⁰, between about 1×10¹⁹ and 1×10²⁰, between about 1×10¹⁷ and 1×10²⁰, or between about 1×10¹⁸ and 1×10²¹. In example embodiments, a lower surface of each p-type trench shield 158 may be at a depth of between 0.5 and 3.0 microns from the upper surface of the semiconductor layer structure 110. In other embodiments, the depth of each p-type trench shield 158 may be between 1.0 and 3.0 microns, between 1.0 and 2.5 microns, between 1.5 and 3.0 microns, between 1.5 and 2.5 microns, or between 0.5 and 2.5 microns. Any of the above dopant concentrations may be matched with any of the above-listed depths for the p-type trench shields 158. The p-type trench shields 158 may act to reduce the electric field levels that form in gate oxide layers (discussed below) during device operation, as will be discussed in greater detail below. The p-type trench shields 158 may be doped to have a higher p-type dopant concentration, a lower p-type dopant concentration, or approximately the same p-type dopant concentration as the lower portions of the p-type support shields 150.

Still referring to FIG. 3D, a first n-type JFET pattern 160 is provided that comprises a plurality of spaced apart n-type first JFET regions 162. Each first JFET region 162 may comprise an implanted region in the semiconductor layer structure 110 that is underneath a respective one of the trench shields 158. Each trench shield 158 thus is interposed between the bottom of a respective one of the gate trenches 180 and an associated first JFET region 162. Each first JFET region 162 may directly contact a respective one of the trench shields 158. Each first JFET region 162 extends into the page in the view of FIG. 3D and may (like the trench shields 158) extend for the full length or substantially the full length of the respective gate trenches 180 that they are underneath. Each first JFET region 162 may have an n-type doping concentration that exceeds a doping concentration of the drift region 120. The n-type doping concentration of each first JFET region 162 may also exceed the doping concentration of the current spreading layer 122. In example embodiments, the n-type doping concentration of each first JFET region 162 may be between 5×10¹⁶ and 1×10¹⁸ dopants/cm³. The doping concentration of each first JFET region 162 may be at least twice the doping concentration of the drift layer 120 in example embodiments. As shown, an upper surface of each first JFET region 162 may be self-aligned with a lower surface of its associated trench shield 158. In example embodiments, each first JFET region 162 may extend over a depth of between 0.1 microns and 1.0 micron (i.e., each first JFET region 162 may extend an additional 0.1-1.0 microns below the bottom surface of its associated trench shield 158).

As is also shown in FIG. 3D, a third n-type JFET pattern 170 is also provided that comprises a plurality of spaced apart n-type third JFET regions 172. Each third JFET region 172 may comprise an implanted region in the semiconductor layer structure 110 that is underneath a respective one of the support shields 150. The third JFET regions 172 may be formed using a standard ion implantation process or a channeled ion implantation process depending upon the desired characteristics for the third JFET regions 172. Each third JFET region 172 extends into the page in the view of FIG. 3D. Each third JFET region 172 may have an n-type doping concentration that exceeds a doping concentration of the drift region 120. The n-type doping concentration of each third JFET region 172 may also exceed the doping concentration of the current spreading layer 122. In example embodiments, the n-type doping concentration of each third JFET region 172 may be between 5×10¹⁶ and 1×10¹⁸ dopants/cm³. The doping concentration of each third JFET region 172 may be at least twice the doping concentration of the drift layer 120 in example embodiments. As shown, an upper surface of each third JFET region 172 may be self-aligned with a lower surface of a corresponding one of the support shields 150. In example embodiments, each third JFET region 172 may extend over a depth of between 0.1 microns and 1.0 micron (i.e., each third JFET region 172 may extend an additional 0.1-1.0 microns below the bottom surface of its associated support shield 150.

The doping concentrations of the first, second and third JFET patterns 160, 170, 126 may be the same or different. The doping concentrations of each of the first, second and third JFET patterns 160, 170, 126 may be higher than the doping concentrations of the drift region 120 and the current spreading layer 122, and the doping concentrations of the current spreading layer 122 may be higher than the doping concentration of the drift region 120. In some embodiments, the doping concentrations of the second and/or third JFET patterns 170, 126 may be higher than the doping concentration of the first JFET pattern 160. It will be appreciated that the doping concentrations that are referred to herein are the peak doping concentrations of the specified layers/regions. The entire layer/region may have the peak doping concentration or only a portion of the layer/region may have the peak doping concentration. The entirety of the first, second and third JFET patterns 160, 170, 126 have doping concentrations that exceed the doping concentration of the drift region 120. The first, second and third JFET patterns 160, 170, 126 may all have the same doping concentration or, alternatively, some or all of the first, second and third JFET patterns 160, 170, 126 may have different doping concentrations. This is true in all of the embodiments disclosed herein. It will also be appreciated that the doping concentrations of the first, second and/or third JFET patterns 160, 170, 126 may be constant or may be graded (e.g., graded with depth).

In FIG. 3D, the first JFET regions 162 are shown as being self-aligned with the respective trench shields 158 and the third JFET regions 172 are shown as being self-aligned with the respective support shields 150. Embodiments of the invention are not limited thereto. The lateral (y-direction) extent of the first and third JFET regions 162, 172 may be varied by selection of the dopant ions implanted (some dopant ions have more lateral straggle than others when implanted) and by the type of implantation method used (e.g., random or channeled implants). Thus, in some embodiments, the lateral width of each first JFET region 162 may by narrower than the lateral width of its associated trench shield 158, while in other embodiments the lateral width of each first JFET region 162 may exceed the lateral width of its associated trench shield 158. Similarly, the lateral width of each third JFET region 172 may by narrower than the lateral width of its associated support shield 150, while in other embodiments the lateral width of each third JFET region 172 may exceed the lateral width of its associated support shield 150.

A gate oxide layer 182 is provided in each gate trench 180 to cover the sidewalls and bottom surface of the gate trench 180. Each gate oxide layer 182 may comprise, for example, a silicon oxide (SiO₂) pattern. The gate oxide layers 182 may or may not be connected to each other outside the view of FIG. 3D. As shown in FIG. 3D, in some embodiments, the gate oxide layers 182 may be formed generally conformally within the respective gate trenches 180.

A gate electrode 184 is formed in each gate trench 180 on the gate oxide layer 182. The gate electrodes 184 may comprise conductive material such as a silicide (e.g., NiSi, TiSi, WSi, CoSi), doped polycrystalline silicon (poly-Si), and/or a stable conductor. Other suitable materials for the gate electrode include various metals such as Ti, Ta or W or metal nitrides such as TiN, TaN or WN. The gate oxide layers 182 may insulate the gate electrodes 184 from the semiconductor layer structure 110, thereby preventing the gate electrodes 184 from short circuiting to the semiconductor layer structure 110. Each gate electrode 184 may connect to one of the gate buses 186 (see FIG. 3B). In the depicted embodiment, the gate electrodes 184 are recessed so that the upper surface of each gate electrode 184 is below an upper surface of the semiconductor layer structure 110. It will be appreciated that in other embodiments the gate electrodes 184 may extend above and onto the upper surface of the semiconductor layer structure 110, with the gate oxide layer 182 insulating the gate electrodes 184 from the upper surface of the semiconductor layer structure 110.

Intermetal dielectric layers 188 are formed that cover each gate electrode 184. The intermetal dielectric layers 188 insulate the source metallization layer 190 from the gate electrodes 184.

A source metallization layer 190 is formed on the upper surface of the semiconductor layer structure 110 and on the intermetal dielectric layers 188. Herein, the source metallization layer 190 may also be referred to as the “source contact.” The source metallization layer 190 may comprise a single metal layer or multiple metal layers. Typically multiple metal layers are provided, as the source metallization layer 190 may include, for example, a single layer or multi-layer adhesion layer that contacts the semiconductor layer structure 110, one or more barrier layers, and a bulk metal layer (e.g., an aluminum layer).

In FIG. 3D, the second JFET pattern 126 is shown as extending deeper into the semiconductor layer structure 110 than the gate trench 180. It will be appreciated, however, that in other embodiments the gate trench 180 may extend deeper into the semiconductor layer structure 110 than the second JFET pattern 126. Likewise, the current spreading layer 122 is shown as extending deeper into the semiconductor layer structure 110 than the trench shield 158 and not as deep as the first JFET pattern 160. It will be appreciated that in other embodiments the current spreading layer 122 may extend deeper into the semiconductor layer structure 110 than the first JFET pattern 126 or may not extend as deeply into the semiconductor layer structure 110 as the trench shield 158.

FIG. 3E is a schematic cross-sectional view taken along line 3E-3E of FIG. 3C that illustrates a trench shield connection pattern 156 of the power MOSFET 100. A plurality of trench shield connection patterns 156 are provided, where each trench shield connection pattern 156 extends in a lateral (y) direction and the trench shield connection patterns 156 are spaced apart from each other along the x-direction. The dashed lines in FIG. 3C illustrate the location of the two trench shield connection patterns 156 that are present in the plan view of FIG. 3C.

As shown in FIGS. 3C and 3E, each trench shield connection pattern 156 may comprise a laterally-extending stripe of p-type material that extends downwardly from the upper surface of the semiconductor layer structure 110. The trench shield connection patterns 156 may have the same or similar p-type doping concentrations as the p-wells 134, the lower portions 152 of the support shields 150 and the trench shields 158 and consequently, as shown in FIG. 3E, the portions of these regions that overlap may merge together into a single p-type region in some embodiments. The trench shield connection patterns 156 electrically connect the trench shields 158 to the source metallization layer 190.

The n-type substrate 110, the n-type drift layer 120, the n-type current spreading layer 122, the n-type second JFET pattern 126, the p-type silicon carbide well regions 134, the n-type source regions 142, the p-type support shields 150, the p-type trench shield connection patterns 156, the p-type trench shields 158, the n-type first JFET pattern 160, and the n-type third JFET pattern 170 may together comprise the semiconductor layer structure 160 of the power MOSFET 100.

The power MOSFET 100 may be turned on by applying a gate bias voltage that is above a threshold level to the gate pad 102. The gate bias voltage is transferred to the gate electrodes 184 via the gate buses 186 and creates conductive n-type inversion layers in the portions of the p-wells 134 that are adjacent the gate trenches 180. These regions of the p-wells 134 are referred to herein as channel regions 136 as current flows from the source regions 142 to the drift region 120 through these channel regions 136 during on-state operation. The channel regions 136 are vertically oriented (i.e., extend in the z direction) as the current flows downwardly from the source regions 142, through the channel regions 136 to the second JFET regions 128, the current spreading layer 122, the drift region 120, the substrate 110 and the drain contact 106.

Each support shield 150 may extend more deeply (i.e., to a greater depth) into the semiconductor layer structure 110 than its associated trench shields 158. In such embodiments, the support shields 150 may act as the primary current path during an avalanche breakdown event. Since power MOSFET 100 has support shields 150 that extend deeper into the semiconductor layer structure 110 than the trench shields 158, any avalanche currents will primarily flow into the support shields 150. This acts to reduce the electric fields in the gate oxide layers 182 during any avalanche breakdown event, helping protect the gate oxide layers 182 from damage during such events.

While the provision of the support shields 150 and the trench shields 158 may help protect the gate oxide layers 182 during reverse blocking operation (and during avalanche breakdown events), the support shields 150 and the trench shields 158 funnel the on-state currents through narrower regions in the semiconductor layer structure 110, which acts to increase the on-state resistance of the device. The first and third JFET patterns 160, 170 are “deep” JFET patterns that may be formed (at least partly, and often completely) in the drift region 120. The first and third JFET regions 162, 172 that form the respective first and third JFET patterns 160, 170 are placed at strategic locations in the drift region 120 where they can help to efficiently spread on-state currents to portions of the drift region 120 that would otherwise not experience as much on-state current flow. The provision of the first and third JFET regions 162, 172 thus may act to reduce the on-state resistance of power MOSFET 100 as compared to a comparable power MOSFET that did not include the first and third JFET patterns 160, 170.

As discussed above, FIGS. 3A-3E illustrate a power MOSFET 100 according to embodiments of the present invention. The MOSFET 100 comprises a semiconductor layer structure 110 that includes at least a drift region 120 having a first conductivity type, a well region 134 having a second conductivity type on the drift region 120, and a first JFET region 162 having the first conductivity type. A first conductivity dopant concentration of the first JFET region 162 exceeds a first conductivity dopant concentration of the drift region 120. A gate trench 180 extends into the semiconductor layer structure 110. An upper surface of the first JFET region 162 is positioned below the gate trench 180.

A trench shield 158 having the second conductivity type may be provided in the semiconductor layer structure 100. The first JFET region 162 vertically overlaps the trench shield 158 and may directly contact the trench shield 158. The trench shield 158 may be in between a bottom of the gate trench 180 and the first JFET region 162. In some embodiments, an upper surface of the first JFET region 162 may be self-aligned with a lower surface of the trench shield 158.

The gate trench 180 may be one of a plurality of gate trenches 180 that extend into an upper surface of the semiconductor layer structure 110, the well region 134 may be one of a plurality of well regions 134 in the semiconductor layer structure 110, and the first JFET region 162 may be one of a plurality of first JFET regions 162 that together form a first JFET pattern 160. Each first JFET region 162 may be below a respective one of the gate trenches 180 and spaced-apart from the other first JFET regions 162. The semiconductor layer structure 110 may further comprise a second JFET pattern 126 that includes a plurality of spaced-apart second JFET regions 128 having the first conductivity type, where each of the second JFET regions 128 has a first conductivity dopant concentration that exceeds the first conductivity dopant concentration of the drift region 120. Each second JFET region 128 is in between the drift region 120 and a respective one of the well regions 134, and an upper surface of each first JFET region 162 is at a greater depth within the semiconductor layer structure 110 than a lower surface of each second JFET region 128.

The semiconductor layer structure 110 may further comprise a current spreading layer 122 having the first conductivity type on the drift region 120, and the first conductivity dopant concentration of the first JFET region 162 may exceed a first conductivity dopant concentration of the current spreading layer 122, and the first conductivity dopant concentration of the current spreading layer 122 may exceed the first conductivity dopant concentration of the drift region 120. An upper surface of the first JFET region 162 is at a greater depth within the semiconductor layer structure 110 than an upper surface of the current spreading layer 122.

The semiconductor layer structure 110 further comprises first and second support shields 150 that each have the second conductivity type and that each extend downwardly from the upper surface of the semiconductor layer structure 110 into the drift region 120, where the gate trench 180 is in between the first and second support shields 150. Additionally, the semiconductor layer structure 110 may further comprise a third JFET pattern 170 that includes a plurality of third JFET regions 172 having the first conductivity type. A first of the third JFET regions 172 is positioned below the first support shield 150 and a second of the third JFET regions 172 is positioned below the second support shield 150. The third JFET regions 172 are spaced-apart from one another. An upper surface of the first JFET region 162 is at a shallower depth in the semiconductor layer structure 110 than upper surfaces of the third JFET regions 172.

FIG. 3F is a schematic top view of the portion of a modified version of the gate trench silicon carbide power MOSFET of FIGS. 3A-3E. The view of FIG. 3F corresponds to the portion of the MOSFET shown in the box labelled A in FIG. 3B. As can be seen by comparing FIGS. 3C and 3F, the only difference between power MOSFET 100 and the modified version thereof shown in FIG. 3F is that the upper portions 154 of the support shields 150 extend continuously the full length of the respective source regions 142 in power MOSFET 100 of FIGS. 3A-3D, while in the modified version of power MOSFET 100 shown in FIG. 3F the support shields 150 include a plurality of spaced apart upper portions 154 that extend through the source regions 142 so that the upper portions 154 of the support shields 150 appear as islands within the source regions 142.

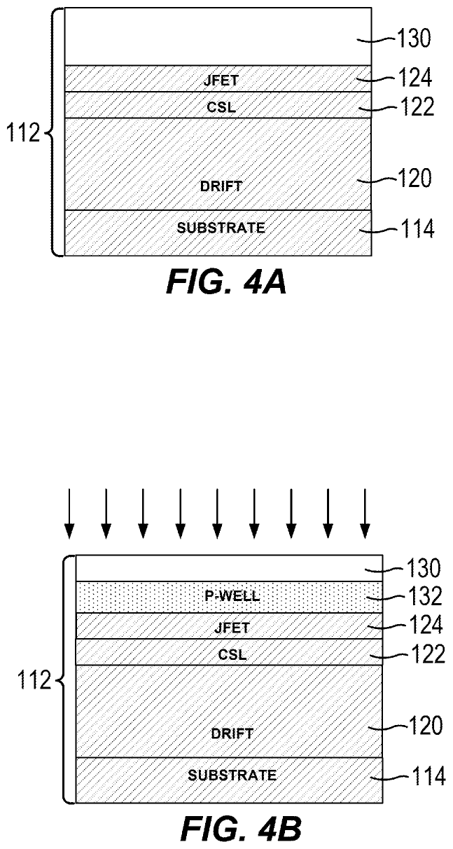

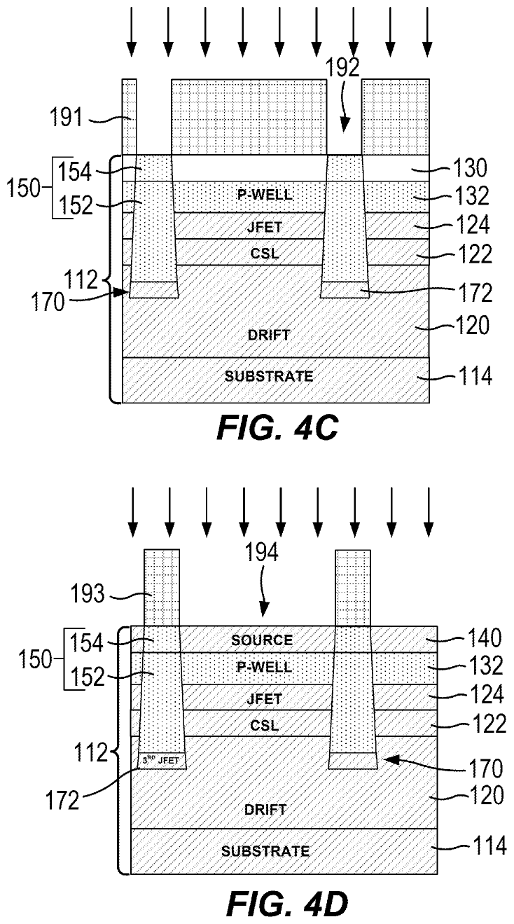

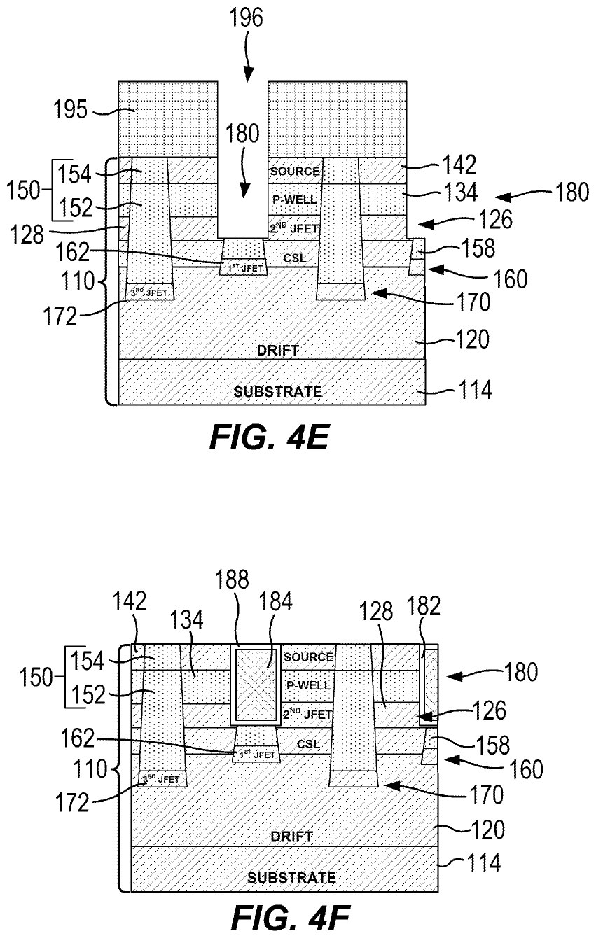

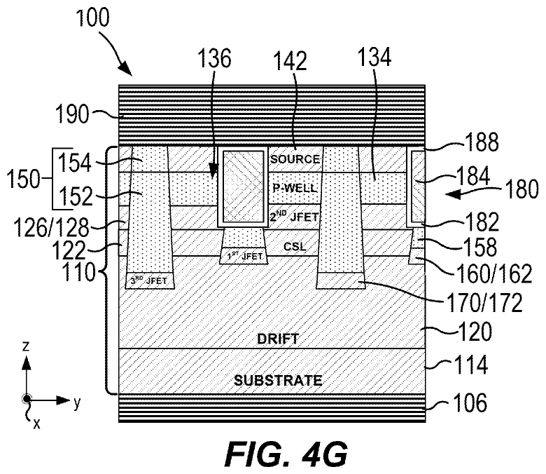

FIGS. 4A-4G are schematic cross-sectional views illustrating a method of fabricating the gate trench silicon carbide power MOSFET 100 of FIGS. 3A-3E. It should be noted that FIGS. 4A-4G do not show the processing steps that are used to form the trench shield connection patterns 156 that are shown in FIG. 3E. U.S. Pat. No. 11,610,991, which is incorporated herein by reference in its entirety, illustrates (see, e.g., FIGS. 2A-2F thereof) a suitable method for forming the trench shielding connection patterns 156.

Referring to FIG. 4A, the n-type silicon carbide substrate 114 is provided. The lightly-doped (n) silicon carbide drift layer 120 is then formed on an upper surface of the substrate 114, typically via epitaxial growth. The n-type dopant concentration may then be increased during the epitaxial growth process to form the more highly doped (n-type) current spreading layer 122 on the upper surface of the drift layer 120, and the n-type dopant concentration may then be increased even further to epitaxially grow an n-type JFET layer 124 on the n-type current spreading layer 122. The epitaxial growth process may then continue (with the n-type dopant source left turned on or turned off) to grow a capping layer 130 on the upper surface of the JFET layer 124. The substrate 114, drift layer 120, current spreading layer 122, JFET layer 124 and capping layer 130 together form a preliminary semiconductor layer structure 112.

Referring to FIG. 4B, p-type dopants are implanted into the upper surface of the preliminary semiconductor layer structure 112 to convert all or a lower part of the capping layer 130 into a p-well layer 132. The p-well layer 130 may have a p-type doping concentration that matches a desired p-type doping concentration for the p-wells 134 that are included in the finished device.

Referring to FIG. 4C, a first mask layer such as, for example, an oxide mask layer is formed on the upper surface of the preliminary semiconductor layer structure 112. The first mask layer is then patterned to form openings 192 therein to provide a first patterned mask 191 that exposes selected portions of the preliminary semiconductor layer structure 112. The openings 192 may be centered above locations in the preliminary semiconductor layer structure 112 in which the support shields 150 and the third JFET pattern 170 will be formed. An ion implantation process is then performed using the first patterned mask 191 as an ion implantation mask to implant n-type dopant ions into the preliminary semiconductor layer structure 112 to form the n-type third JFET regions 172. The third JFET regions 172 may be formed using a relatively high energy channeled ion implantation process in example embodiments. The third JFET regions 172 may be buried regions that do not extend to the upper surface of the preliminary semiconductor layer structure 112, with most of the ions implanted in the third JFET regions 172, although some amount of straggle will exist where n-type ions are implanted at shallower depths in the preliminary semiconductor layer structure 112. The third JFET regions 172 are spaced apart from each other and together form a buried third JFET pattern 170 in the preliminary semiconductor layer structure 112.

Still referring to FIG. 4C, next another ion implantation process is performed, again using the first patterned mask 191 as an ion implantation mask, to implant p-type dopant ions into the preliminary semiconductor layer structure 112 to form the p-type support shields 150. This ion implantation process may include, for example, a high-energy, moderate dose ion implantation (or a channeled ion implantation) to form the lower portion 152 of each support shield 150, as well as a low-energy, high dose ion implantation that forms the upper portion 154 of each support shield 150. As shown in FIG. 4C, the upper portion 154 of each support shield 150 may be heavily doped p-type (p+) while the remainder of each support shield 150 may be moderately doped p-type (p). The p-type dopant concentration used to form the lower portion 152 of each support shield 150 is sufficient to readily overcome the straggle of n-type dopants that remain in upper portions of the preliminary semiconductor layer structure 112 from the ion implantation process used to form the buried third JFET pattern 170. Since the same patterned ion implantation mask 191 is used for the ion implantation processes that form the third JFET regions 172 and the support shields 150, the upper surface of each third JFET region 172 may be self-aligned with a lower surface of a respective one of the support shields 150. The first patterned mask 191 may then be removed.

Referring to FIG. 4D, a second mask layer is formed on the upper surface of the preliminary semiconductor layer structure 112 and patterned to form a second patterned mask 193. An ion implantation process is performed using the second patterned mask 193 as an ion implantation mask to implant n-type ions into the remaining portion of the capping layer 130 to convert the remaining portion of the capping layer 130 into a heavily doped (n+) n-type source layer 140. The second ion implantation process may be a low energy, high dosage ion implantation step. The second patterned mask 193 may then be removed.

Referring to FIG. 4E, a third patterned mask 195 may be formed that has openings 196 that expose portions of the preliminary semiconductor layer structure 112 where the gate trenches 180 will be formed. Next, an etching process is performed to form the gate trenches 180 in the preliminary semiconductor layer structure 112. As shown, in some embodiments the gate trenches 180 may not extend as deep into the preliminary semiconductor layer structure 112 as the bottoms of the support shields 150. The formation of the gate trenches 180 converts the well layer 132 into the plurality of p-wells 134 and converts the source layer 140 into a plurality of source regions 142. Next, an ion implantation process is performed using the third patterned mask 195 as an implant mask to implant n-type dopant ions into the preliminary semiconductor layer structure 112 to form a plurality of first JFET regions 162. The first JFET regions 162 may be formed using a relatively moderate energy, high dosage ion implantation process in example embodiments. The first JFET regions 162 may be buried regions that have upper surfaces that are below the bottom surfaces of the gate trenches 180, although some amount of straggle will exist where n-type ions are implanted in the current spreading layer 122 in between the first JFET regions 162 and the respective gate trenches 180. The first JFET regions 162 are spaced apart from each other and together form a buried first JFET pattern 160 in the preliminary semiconductor layer structure 112.

Next, another ion implantation process is performed using the third patterned mask 195 as an implant mask to implant p-type dopant ions into the portions of the preliminary semiconductor layer structure 112 that are underneath the gate trenches 180 to form a plurality of trench shields 158. As shown, each trench shields 158 is interposed in between the bottom of a gate trench 180 and a respective one of the first JFET regions 162. Since the same patterned ion implantation mask 195 is used for the ion implantation processes that form the first JFET regions 162 and the trench shields 158, the upper surface of each first JFET region 162 may be self-aligned with a lower surface of a respective one of the trench shields 158. The third patterned mask 195 may then be removed.

The processing steps described above with respect to FIG. 4E convert the preliminary semiconductor layer structure 112 into the semiconductor layer structure 110.

Referring to FIG. 4F, the gate oxide layers 182 and gate electrodes 184 may then be formed in the gate trenches 180, and the intermetal dielectric layers 188 are formed to cover the gate oxide layers 182 and gate electrodes 184. Referring to FIG. 4G, the source metallization layer 190 is then formed on the source regions 142, the intermetal dielectric layers 188, and the upper portions 152 of the support shields 150. The drain pad 106 is then formed on the bottom of the substrate 114.

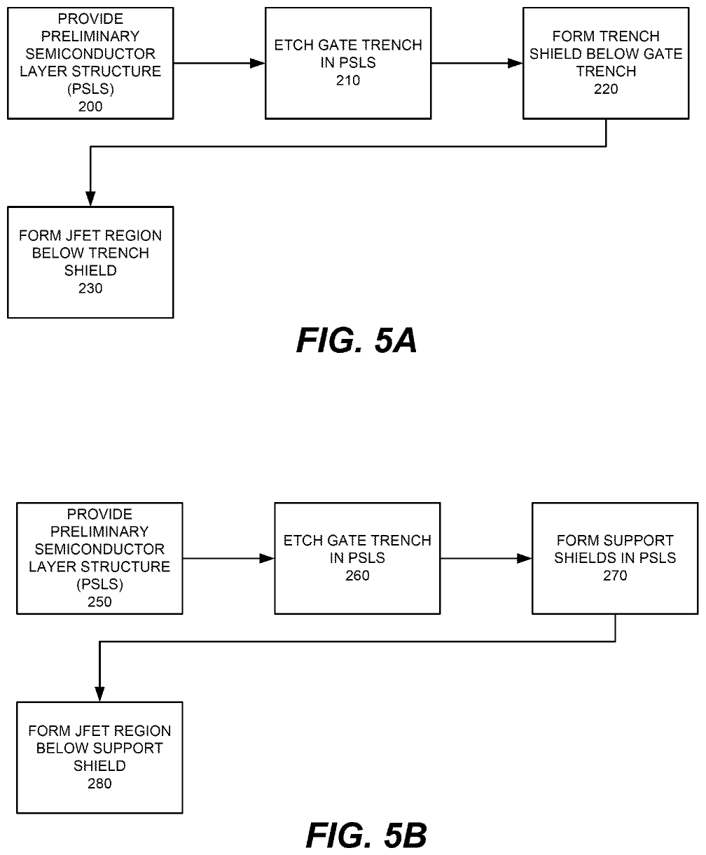

FIG. 5A is a flow chart illustrating a method of forming a gate trench silicon carbide power MOSFET according to embodiments of the present invention. As shown in FIG. 5A, first a silicon carbide based preliminary semiconductor layer structure 112 is provided (Block 200). The preliminary semiconductor layer structure 112 includes a drift layer 120 having a first conductivity type. Next, a gate trench 180 is formed in the preliminary semiconductor layer structure 112 by, for example, forming an etch mask on the upper surface of the preliminary semiconductor layer structure 112, patterning the etch mask to expose a selected region of the preliminary semiconductor layer structure 112 where the gate trench 180 will be formed, and then etching the exposed portion of the semiconductor layer structure 110 to form the gate trench 180 in the preliminary semiconductor layer structure 112 (Block 210). While only one gate trench is mentioned here, it will be appreciated that typically a large number of gate trenches are formed in this etching step.

Next, second conductivity type dopants are selectively implanted into the preliminary semiconductor layer structure 112 to form a trench shield 158 in the preliminary semiconductor layer structure 112 underneath the gate trench 180 (Block 220). A patterned ion implantation mask that exposes the gate trench 180 may be used during this ion implantation process. The second conductivity type dopants may be implanted directly into the semiconductor material forming the bottom of the gate trench 180. Next, first conductivity type dopants are selectively implanted into the preliminary semiconductor layer structure 112 to form a first JFET region 162 in the preliminary semiconductor layer structure 112 underneath the gate trench 180 (Block 230). The first JFET region 162 may be formed at a greater depth than the trench shield 158 so that the trench shield 158 is in between the bottom of the gate trench 180 and the first JFET region 162. The trench shield 158 may be in between the gate trench 180 and the first JFET region 162. The same patterned ion implantation mask that is used during the ion implantation process that forms the trench shield 158 may be used during the ion implantation process used to form the first JFET region 162.

It will be appreciated that the processing steps discussed above with reference to FIG. 5A could be performed in different orders in further embodiments. For example, the processes of Blocks 220 and 230 cold be performed in reverse order. It will also be appreciated that some of the processing steps could be omitted in other embodiments, and/or that other processing steps may be added to the method.

FIG. 5B is a flow chart illustrating another method of forming a gate trench silicon carbide power MOSFET according to embodiments of the present invention. As shown in FIG. 5B, first a silicon carbide based preliminary semiconductor layer structure 112 is provided (Block 250). The preliminary semiconductor layer structure 112 includes a drift layer 120 having a first conductivity type. Next, a gate trench 180 is formed in the preliminary semiconductor layer structure 112 by, for example, forming an etch mask on the upper surface of the preliminary semiconductor layer structure 112, patterning the etch mask to expose a selected region of the preliminary semiconductor layer structure 112 where the gate trench 180 will be formed, and then etching the exposed portion of the semiconductor layer structure 110 to form the gate trench 180 in the preliminary semiconductor layer structure 112 (Block 260). While only one gate trench is mentioned here, it will be appreciated that typically a large number of gate trenches are formed in this etching step.

Next, second conductivity type dopants are selectively implanted into the preliminary semiconductor layer structure 112 to form a support shield 150 in the preliminary semiconductor layer structure 112 underneath the gate trench 180 (Block 270). A patterned ion implantation mask that exposes the gate trench 180 may be used during this ion implantation process. The second conductivity type dopants may be implanted directly into the semiconductor material forming the bottom of the gate trench 180. Next, first conductivity type dopants are selectively implanted into the preliminary semiconductor layer structure 112 to form a third JFET region 172 in the preliminary semiconductor layer structure 112 underneath the support shield 150 (Block 280). The same patterned ion implantation mask that is used during the ion implantation process that forms the support shield 150 may be used during the ion implantation process used to form the third JFET region 172.

It will be appreciated that the processing steps discussed above with reference to FIG. 5B could be performed in different orders in further embodiments. For example, the processes of Blocks 270 and 280 cold be performed in reverse order. It will also be appreciated that some of the processing steps could be omitted in other embodiments, and/or that other processing steps may be added to the method

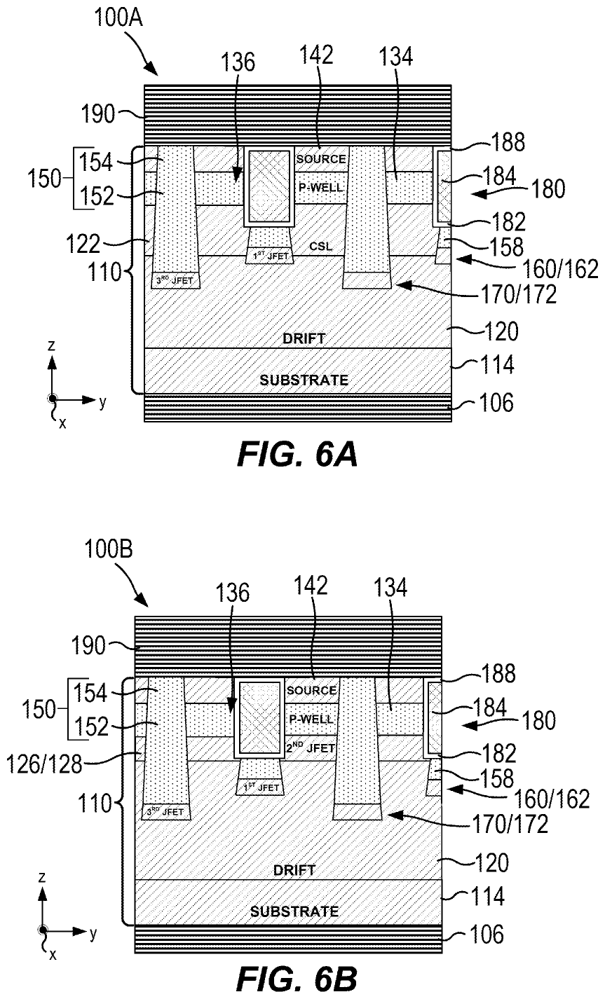

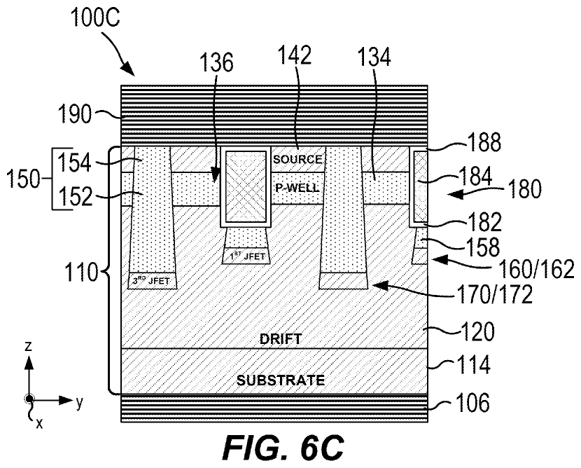

FIGS. 6A-6C are schematic cross-sectional views of gate trench silicon carbide power MOSFETs 100A-100C, respectively, that are modified versions of the gate trench silicon carbide power MOSFET 100. Gate trench silicon carbide power MOSFETs 100A-100C are similar to MOSFET 100, so the discussion below will focus solely on the difference between each of MOSFETs 100A-100C and MOSFET 100.

As can be seen by comparing FIGS. 3D and FIG. 6A, MOSFET 100A differs from MOSFET 100 in that the second JFET pattern 126 is omitted in MOSFET 100A and the current spreading layer 122 extends farther upwardly to contact the p-wells 134. Otherwise, MOSFET 100A may be identical to MOSFET 100. Since the current spreading layer 122 is more lightly doped than the second JFET pattern 126, MOSFET 100A will exhibit an increased on-state resistance and improved reliability as compared to MOSFET 100.

Referring to FIG. 6B, a MOSFET 100B is depicted that is similar to MOSFET 100 of FIGS. 3A-3E, but the current spreading layer 122 that is included in MOSFET 100 is omitted in MOSFET 100B and the drift region 120 extends further upwardly to contact the second JFET regions 128. Otherwise, MOSFET 100B may be identical to MOSFET 100. Since the current spreading layer 122 is more heavily doped than the drift region 120, MOSFET 100B will exhibit an increased on-state resistance and improved reliability as compared to MOSFET 100.

Referring to FIG. 6C, a MOSFET 100C is depicted that is similar to MOSFET 100A of FIG. 6A, but both the current spreading layer 122 and the second JFET pattern 126 that are included in MOSFET 100 are omitted in MOSFET 100C, and the drift region 120 extends further upwardly in power MOSFET 100C to contact the p-wells 134. Otherwise, MOSFET 100C may be identical to MOSFET 100. MOSFET 100C will exhibit an increased on-state resistance and improved reliability as compared to MOSFET 100.

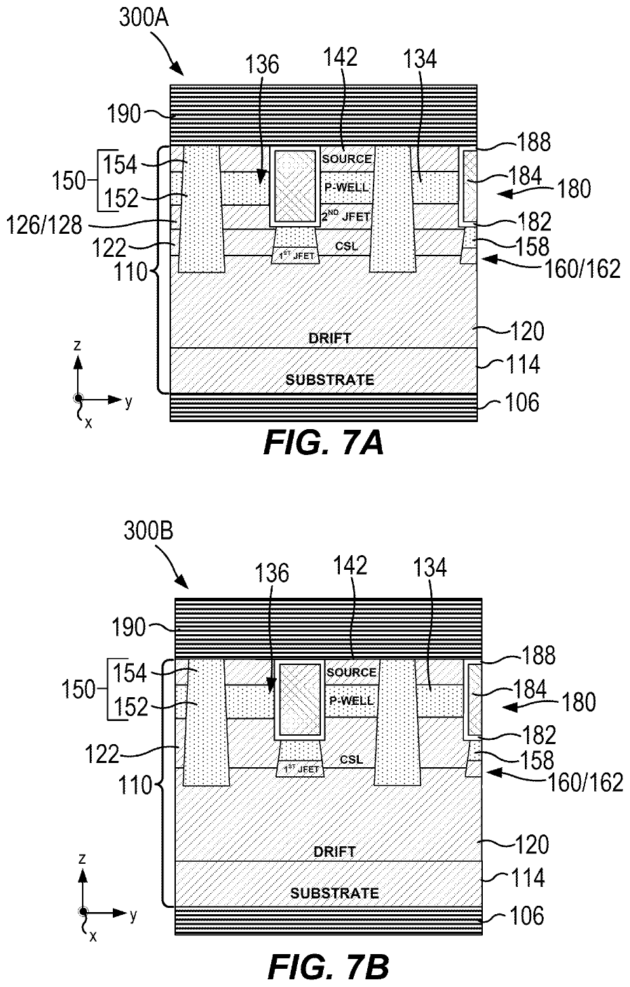

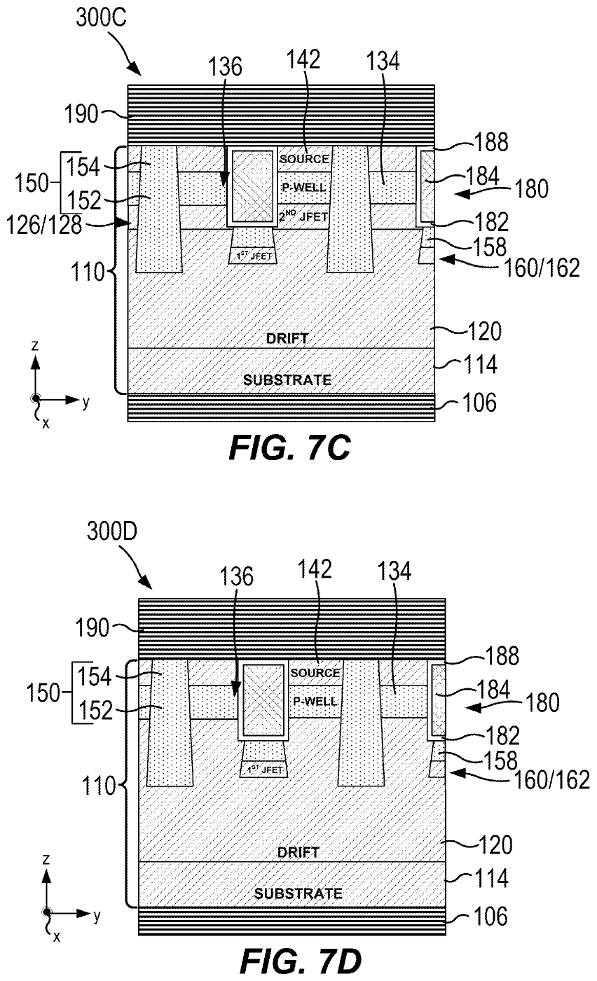

It will also be appreciated that in other embodiments, the third JFET pattern 170 of power MOSFETS 100 and 100A-100C of FIGS. 3A-3E and 6A-6C may be omitted. FIGS. 7A-7D are cross-sectional views of power MOSFETS 300A-300D which are modified versions of power MOSFETS 100 and 100A-100C, respectively, in which the third JFET patterns that are included in power MOSFETS 100 and 100A-100C are omitted. As power MOSFETS 300A-300D otherwise are identical to power MOSFETS 100 and 100A-100C, respectively, further description thereof will be omitted.

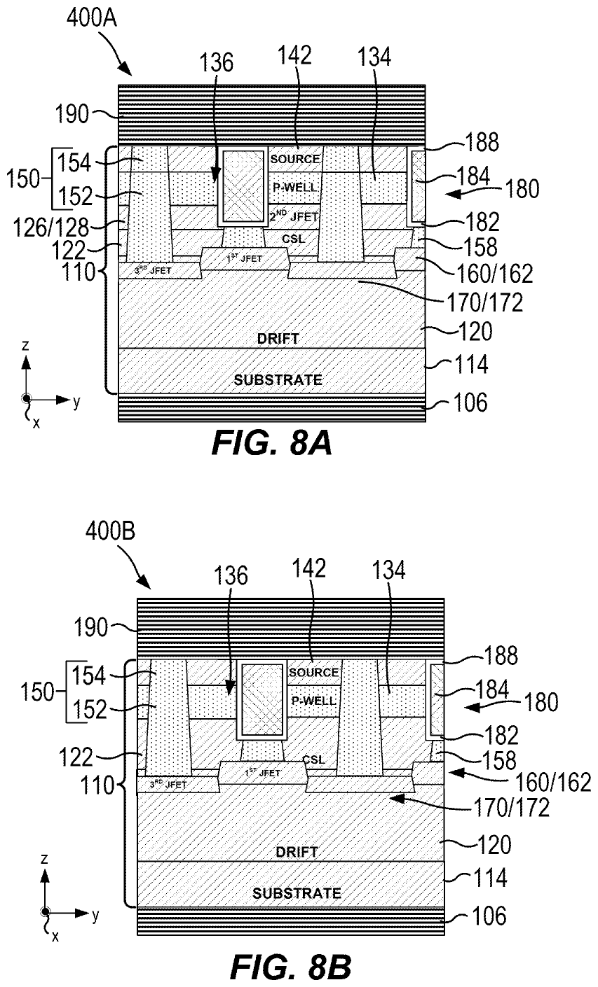

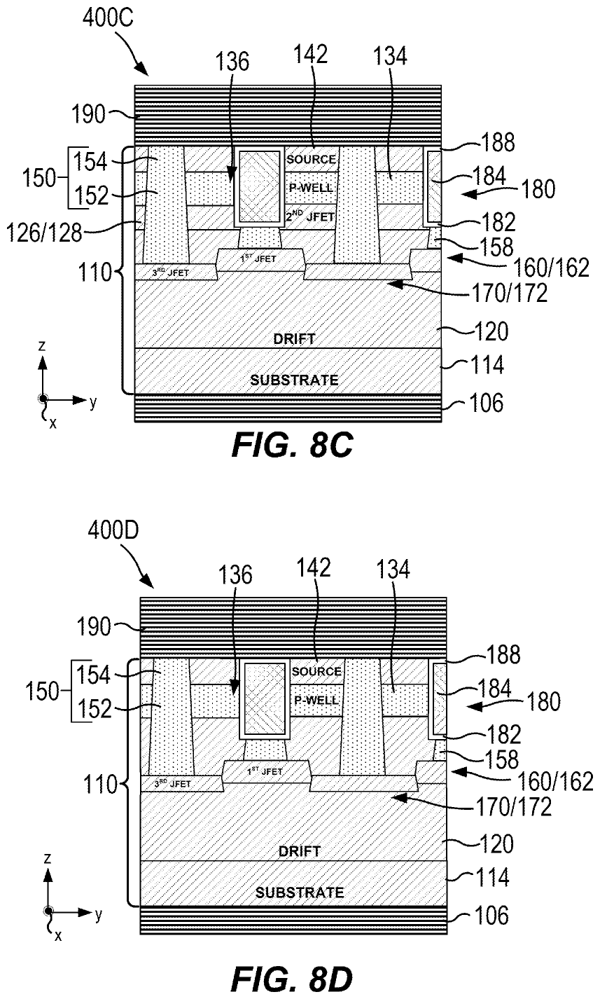

FIGS. 8A-8D are schematic cross-sectional views of gate trench silicon carbide power MOSFETs 400A-400D according to yet additional embodiments of the present invention. Power MOSFETs 400A-400D are similar to power MOSFETS 100 and 100A-100C of FIGS. 3A-3E and 6A-6C, so the description below will focus on the differences between these power MOSFETS. FIGS. 3A-3C accurately depict power MOSFETs 400A-400D and the cross-sectional views of FIGS. 8A-8D are taken along lines 3D-3D and 3E-3E, respectively, of FIG. 3C.

As can be seen by comparing FIGS. 3D and FIG. 8A, power MOSFET 400A differs from power MOSFET 100 in that in power MOSFET 400A the first JFET regions 162 and the third JFET regions 172 each spread further laterally (i.e., in the y direction) so that each third JFET regions 172 merges with the first JFET regions 162 on either side thereof. The first and third JFET regions 162, 172 may be offset from each other in the vertical direction as shown (here the third JFET regions 172 extend deeper into the semiconductor layer structure 110 than the first JFET regions 162 since the support shields 150 extend deeper into the semiconductor layer structure 110 than the trench shields 158), as shown in FIG. 8A. However, in other embodiments, the third JFET regions 172 may be horizontally aligned with the first JFET regions 162. It will be appreciated that the power MOSFET 400A may be designed so that the third JFET regions 172 merge with the first JFET regions 162 either by implanting using dopant species and/or implantation techniques that lead to increased horizontal straggle of the dopant ions (which increases the lateral widths of the first and third JFET regions 162, 172) or by reducing the pitch of the power MOSFET 400A so that the distance between the support shields 150 and the gate trenches 180 is reduced. Otherwise, power MOSFET 400A may be identical to power MOSFET 100, so further description thereof will be omitted.

By laterally enlarging the first and third JFET regions 162, 172 the on-state resistance of power MOSFET 400A may be reduced as compared to power MOSFET 100. The increased doping concentration however, will tend to increase the electrical field levels during reverse blocking operation and hence the improvement in on-state resistance may come at the cost of a countervailing decrease in reliability. Power MOSFETS 400B-400D of FIGS. 8B-8D are identical to power MOSFETS 400B-400D of FIGS. 6A-6C, respectively, except that power MOSFETS 400B-400D each further include first and third JFET regions 162, 172 that merge together in the fashion discussed above with reference to FIG. 8A.

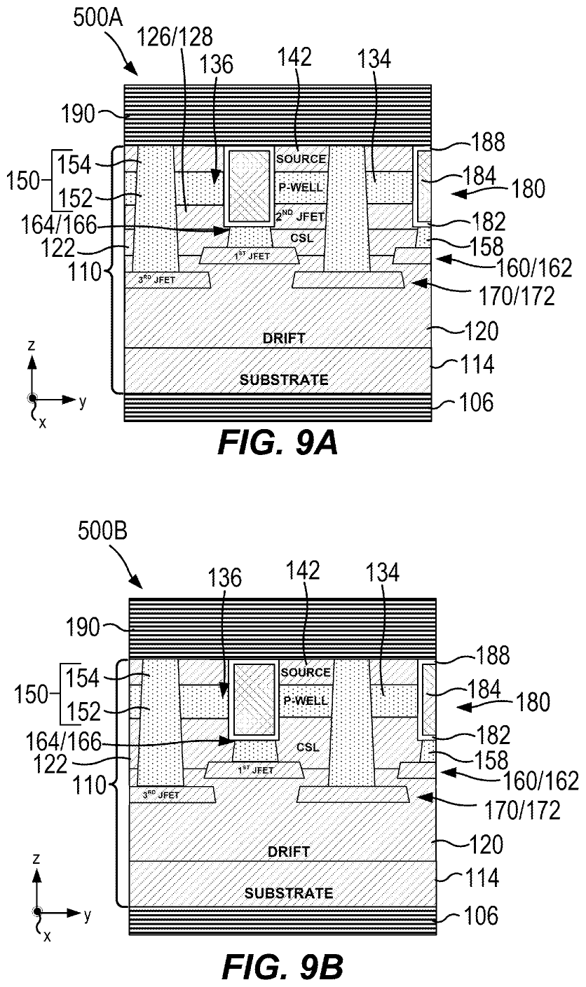

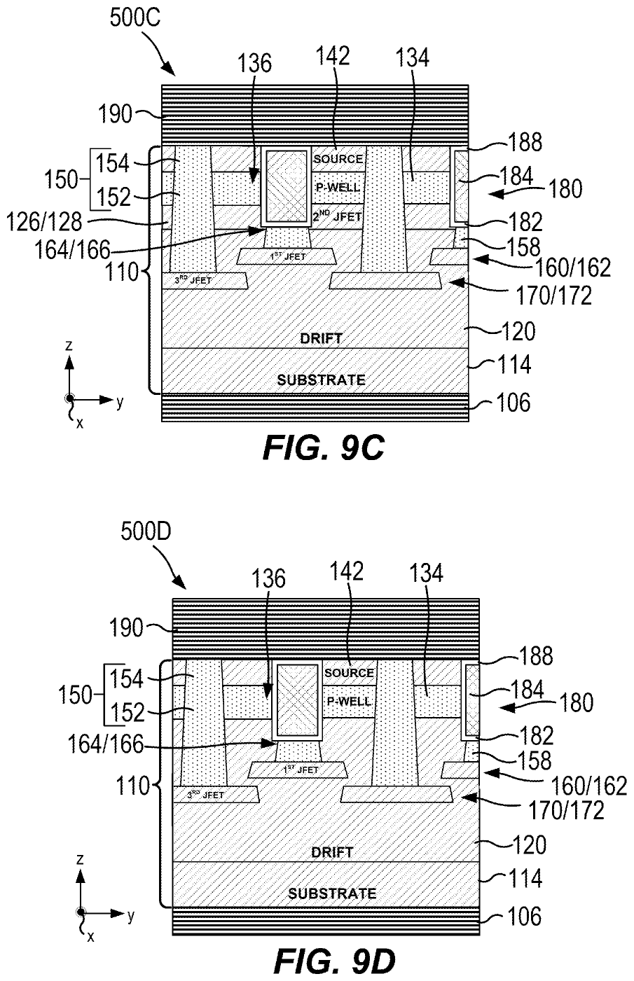

It will also be appreciated that, in other embodiments, the first and third JFET regions 162, 172 may have expanded widths as discussed above with reference to FIGS. 8A-8D, but may not merge together. For example, FIG. 9A is a cross-sectional views of power MOSFETS 500A which has laterally widened first and third JFET regions 162, 172. However, in power MOSFET 500A, the support shields 150 extend deeper into the semiconductor layer structure 110 than the trench shields 158 by an amount that exceeds an extent of the first and third JFET regions 162, 172 in the depth (z) direction. As a result, in power MOSFET 500A, each first JFET region 162 may vertically overlap two third JFET regions 172 without merging with the two third JFET regions 172 due to the vertical offset between the first and third JFET regions 162, 172. The design of power MOSFET 500A may be advantageous because avalanche currents will almost exclusively flow through the support shields 150 since the support shields extend significantly deeper into the semiconductor layer structure than the trench shields 158.

FIGS. 9B-9D are cross-sectional views of power MOSFETS 500B-500D which correspond to the power MOSFETS 100A-100C of FIGS. 6A-6C, respectively, but which have the laterally-expanded and vertically offset first and third JFET regions 162, 172 of power MOSFET 500A. As power MOSFETS 500B-500D otherwise are identical to power MOSFETS 100A-100C, respectively, further description thereof will be omitted.

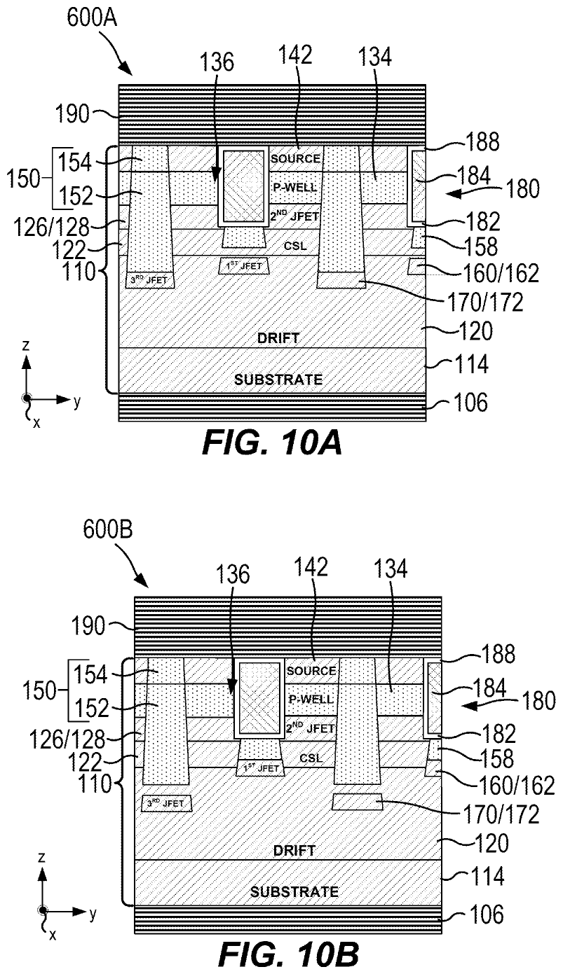

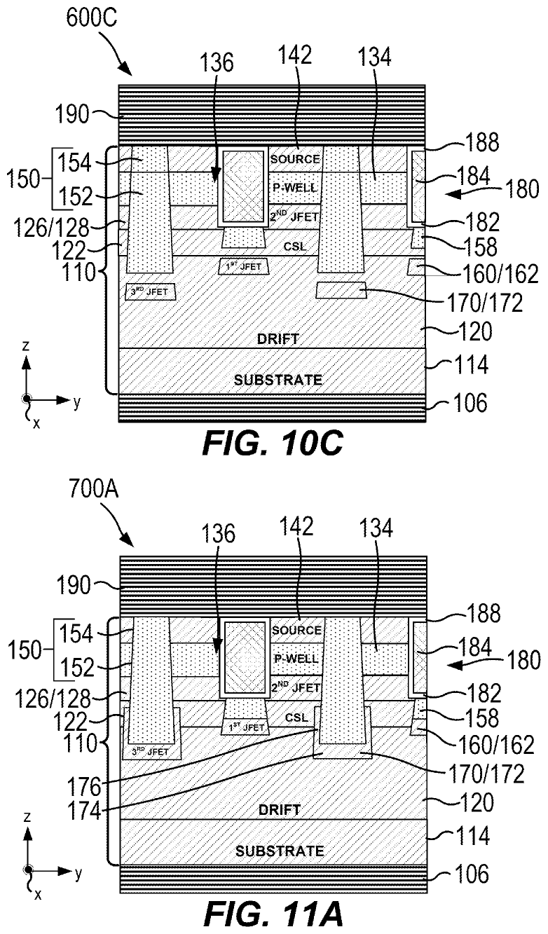

FIG. 10A is a schematic cross-sectional view of a gate trench silicon carbide power MOSFET 600A according to still further embodiments of the present invention. Gate trench power MOSFET 600A is similar to power MOSFET 100, but the first JFET regions 162 that form the first JFET pattern 160 are formed at a greater depth in the semiconductor layer structure 110 so that portions of the current spreading layer 122 and/or the drift region 120 are provided in between each first JFET region 162 and its associated trench shield 158. This modification may help reduce the increase in the electric field levels in the gate oxide layers 182 that are caused by the provision of the first JFET pattern 160, since the first JFET regions 162 is spaced further from the gate trenches 180. Moreover, spacing the first JFET regions 162 apart from the trench shields may have little impact on the on-state resistance performance.

FIGS. 10B and 10C are schematic cross-sectional views of gate trench silicon carbide power MOSFETS 600B, 600C, respectively, that are modified versions of power MOSFET 600A. As shown in FIG. 10B, in power MOSFET 600B, the third JFET regions 172 that form the third JFET pattern 170 are formed at a greater depth in the semiconductor layer structure 110 so that portions of the current spreading layer 122 and/or the drift region 120 are provided in between each third JFET region 172 and its associated support shield 150. In power MOSFET 600B, the first JFET regions 162 are formed at the same depths as the first JFET regions 162 of power MOSFET 100 so that the first JFET regions 162 in power MOSFET 600B directly contact the bottoms of the respective trench shields 158. As shown in FIG. 10C, in power MOSFET 600C, both the first and third JFET regions 162, 172 are formed at greater depths in the semiconductor layer structure 110 as compared to the corresponding regions of power MOSFET 100 so that portions of the current spreading layer 122 and/or the drift region 120 are provided in between each first JFET region 162 and its associated trench shield 150 and in between each third JFET region 172 and its associated support shield 150.

It will be appreciated that the power MOSFETS of FIGS. 6A-9D may all be modified in the same manner as shown in FIGS. 10A-10C to have first and/or third JFET regions 162, 172 that are formed to be spaced-apart from their associated trench shields 158 and/or support shields 150.

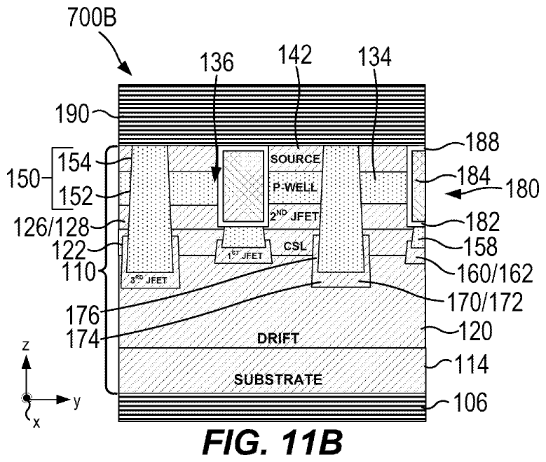

FIG. 11A is a schematic cross-sectional view of gate trench silicon carbide power MOSFET 700A that is yet another modified version of power MOSFET 100. As shown in FIG. 11A, in power MOSFET 700A, each third JFET region 172 is provided not only below its associated support shield 150, but also extends along the sidewalls of its associated support shield 150. Thus, each third JFET region 172 has a bottom portion 174 and a pair of upwardly extending support shield sidewall lining portions 176. The third JFET regions 172 shown in FIG. 11A may be formed by making each third JFET region 172 to be much thicker (i.e., to extend much further in the depth (z) direction) as compared to the third JFET regions 172 of power MOSFET 100. Then, the ion implantation step that forms the support shields 150 may be used to convert the upper middle portion of each third JFET region 172 into the bottom portions 152 of the respective support shields 150, thereby forming third JFET regions 172 that have the shape shown in FIG. 11A (it will be noted that the ion implantation step used to form the support shields 150 may be performed before or after the ion implantation step used to form the third JFET pattern 170).

The doping concentration of the bottom portion 174 of each third JFET region 172 may be the same or different than the doping concentration of the upwardly extending support shield sidewall lining portions 176. In some embodiments, the doping concentration of the bottom portion 174 of each third JFET region 172 may be greater than the doping concentration of the upwardly extending support shield sidewall lining portions 176. In other embodiments, the doping concentration of the bottom portion 174 of each third JFET region 172 may be less than the doping concentration of the upwardly extending support shield sidewall lining portions 176. The upwardly extending support shield sidewall lining portions 176 of each third JFET region 172 may be very effective at spreading the current during on-state operation to flow underneath the support shields 150, and hence may improve the on-state resistance of power MOSFET 700A as compared to power MOSFET 100. Moreover, it is anticipated that the provision of the upwardly extending support shield sidewall lining portions 176 will have only minimal impact on the reliability of power MOSFET 700A.

While in FIG. 11A, each third JFET region 172 extends along the sidewalls of its associated support shield 150 all the way to the p-well 132, it will be appreciated that embodiments of the present invention are not limited thereto, and that the third JFET regions 172 alternatively may only extend part of the way up the sidewalls of the support shields 150 toward the p-wells 134.

FIG. 11B is a schematic cross-sectional view of gate trench silicon carbide power MOSFET 700B that is a modified version of power MOSFET 700A. As shown in FIG. 11B, in power MOSFET 700B, each first JFET region 162 is provided not only below its associated trench shield 158, but also extends along the sidewalls of its associated trench shield 158. While in the embodiment of FIG. 11B, both the first JFET regions 162 and the third JFET regions 172 extend along the sidewalls of their associated trench shields 158 or support shields 150, it will be appreciated that in still other embodiments only the first JFET region 162 may extend along the sidewalls of their associated trench shields 158, and the third JFET regions 172 may not extend along the sidewalls of their associated support shields 150.

Additionally, while the power MOSFETs 700A, 700B of FIGS. 11A-11B are examples where power MOSFET 100 of FIGS. 3A-3E is modified to have third JFET regions 172 that include upwardly extending support shield sidewall lining portions 176 and/or to have to have first JFET regions 162 that include upwardly extending trench shield sidewall lining portions, it will be appreciated that one or both of these modifications may be made to every embodiment of the present invention disclosed herein that includes a first JFET pattern 160 and/or a third JFET pattern 170.

In the description above, each example embodiment has a certain conductivity type. It will be appreciated that opposite conductivity type devices may be formed by simply reversing the conductivity of the n-type and p-type layers in each of the above embodiments. Thus, it will be appreciated that the present invention covers both n-channel and p-channel devices for each different device structure (e.g., MOSFET, IGBT, etc.).

The present invention has primarily been discussed above with respect to silicon carbide based power semiconductor devices. It will be appreciated, however, that silicon carbide is used herein as an example and that the devices discussed herein may be formed in any appropriate wide band-gap semiconductor material system. As an example, gallium nitride based semiconductor materials (e.g., gallium nitride, aluminum gallium nitride, etc.) may be used instead of silicon carbide in any of the embodiments described above.

Embodiments of the present invention have been described above with reference to the accompanying drawings, in which embodiments of the invention are shown. It will be appreciated, however, that this invention may, however, be embodied in many different forms and should not be construed as limited to the embodiments set forth above. Rather, these embodiments are provided so that this disclosure will be thorough and complete, and will fully convey the scope of the invention to those skilled in the art. Like numbers refer to like elements throughout.

Herein, the term “plurality” means two or more. Herein, “substantially” means within +/−10%.

It will be understood that, although the terms first, second, etc. are used throughout this specification to describe various elements, these elements should not be limited by these terms. These terms are only used to distinguish one element from another. For example, a first element could be termed a second element, and, similarly, a second element could be termed a first element, without departing from the scope of the present invention. The term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “top” or “bottom” may be used herein to describe a relationship of one element, layer or region to another element, layer or region as illustrated in the figures. It will be understood that these terms are intended to encompass different orientations of the device in addition to the orientation depicted in the figures.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Embodiments of the invention are also described with reference to a flow chart. It will be appreciated that the steps shown in the flow chart need not be performed in the order shown.

Some embodiments of the invention are described with reference to semiconductor layers and/or regions which are characterized as having a conductivity type such as n-type or p-type, which refers to the majority carrier concentration in the layer and/or region. Thus, n-type material has a majority equilibrium concentration of negatively charged electrons, while p-type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments of the invention and, although specific terms are employed, they are used in a generic and descriptive sense only and not for purposes of limitation, the scope of the invention being set forth in the following claims.

1. A semiconductor device, comprising:
a semiconductor layer structure comprising a drift region having a first conductivity type, a well region having a second conductivity type on the drift region, and a first junction field effect (“JFET”) pattern having the first conductivity type; and
a first gate trench and a second gate trench that each extend into the semiconductor layer structure,
wherein the first JFET pattern comprises a plurality of first JFET regions, where a first of the first JFET regions is below and vertically overlapping the first gate trench and a second of the first JFET regions is below and vertically overlapping the second gate trench, and
wherein first conductivity dopant concentrations of the respective first and second of the first JFET regions each exceed a first conductivity dopant concentration of the drift region, and the first and second of the first JFET regions are spaced apart from each other.

2. (canceled)

3. The semiconductor device of claim 12, wherein the semiconductor layer structure further comprises a trench shield having the second conductivity type that is in between a bottom of the first gate trench and the first of the first JFET regions.

4-8. (canceled)

9. The semiconductor device of claim 3, wherein the semiconductor layer structure further comprises a first support shield and a second support shield that each have the second conductivity type and that each extend downwardly from the upper surface of the semiconductor layer structure into the drift region, where the first gate trench is in between the first support shield and the second support shield.

10. The semiconductor device of claim 9, wherein the semiconductor layer structure further comprises a third JFET pattern that includes a plurality of third JFET regions having the first conductivity type, wherein a first of the third JFET regions is below and vertically overlaps the first support shield and a second of the third JFET regions is below and vertically overlaps the second support shield.

11. The semiconductor device of claim 10, wherein the first of the third JFET regions is spaced-apart from the second of the third JFET regions.

12. (canceled)

13. The semiconductor device of claim 11, wherein an upper surface of the first of the first JFET regions is at a shallower depth in the semiconductor layer structure than upper surfaces of the first and second of the third JFET regions.

14. The semiconductor device of claim 10, wherein the first of the third JFET regions extends along lower sidewalls of the first support shield.

15-17. (canceled)

18. A semiconductor device, comprising:
a semiconductor layer structure; and
a plurality of gate trenches extending into the semiconductor layer structure,
wherein the semiconductor layer structure comprises:
a drift region having a first conductivity type;
at least one well region having a second conductivity type on the drift region;
a plurality of trench shields having the second conductivity type positioned below the respective gate trenches;
a first junction field effect (“JFET”) pattern having the first conductivity type, the first JFET pattern comprising a plurality of spaced-apart first JFET regions that are positioned below and vertically overlaps the respective trench shields,
wherein a first conductivity type dopant concentration of each first JFET region exceeds a first conductivity type dopant concentration of the drift region.

19. (canceled)

20. The semiconductor device of claim 18, wherein each first JFET region directly contacts a respective one of the trench shields.

21. The semiconductor device of claim 18, wherein an upper surface of each first JFET region is self-aligned with a lower surface of a respective one of the trench shields.

22. The semiconductor device of claim 18, wherein the semiconductor layer structure further comprises a second JFET pattern having the first conductivity type and a first conductivity dopant concentration that exceeds the first conductivity dopant concentration of the drift region, where the second JFET pattern comprises a plurality of second JFET regions, with each second JFET region in between the drift region and a respective one of the well regions.

23. The semiconductor device of claim 22, wherein an upper surface of each first JFET region is at a greater depth within the semiconductor layer structure than a lower surface of each second JFET region.

24. The semiconductor device of claim 18, wherein the semiconductor layer structure further comprises a current spreading layer having the first conductivity type in an upper portion of the drift region, and a first conductivity dopant concentration of the first JFET pattern exceeds a first conductivity dopant concentration of the current spreading layer, and the first conductivity dopant concentration of the current spreading layer exceeds the first conductivity dopant concentration of the drift region.

25. The semiconductor device of claim 24, wherein an upper surface of each first JFET region is at a greater depth within the semiconductor layer structure than an upper surface of the current spreading layer.

26. The semiconductor device of claim 18, wherein the semiconductor layer structure further comprises a first support shield and a second support shield that each have the second conductivity type and that each extend downwardly from the upper surface of the semiconductor layer structure into the drift region, and wherein a first of the gate trenches is in between the first support shield and the second support shield, and wherein the semiconductor layer structure further comprises a third JFET pattern that includes a plurality of third JFET regions having the first conductivity type, wherein a first of the third JFET regions is positioned below and vertically overlaps the first support shield and a second of the third JFET regions is positioned below and vertically overlaps the second support shield and spaced apart from the first of the third JFET regions.

27-29. (canceled)

30. The semiconductor device of claim 2627, wherein the first of the third JFET regions extends along lower sidewalls of the first support shield.

31-32. (canceled)

33. A semiconductor device, comprising:
a semiconductor layer structure comprising:
a drift region having a first conductivity type;
a current spreading layer having the first conductivity type and a first conductivity dopant concentration that exceeds a first conductivity dopant concentration of the drift region on the drift region;
a well region having a second conductivity type above the current spreading layer; and
a first junction field effect (“JFET”) pattern having the first conductivity type that has a lower surface that extends deeper into the semiconductor layer structure than a lower surface of the current spreading layer, where the first JFET pattern includes a plurality of spaced apart first JFET regions, each of which has a first conductivity dopant concentration that exceeds a first conductivity dopant concentration of the current spreading layer; and
a gate trench extending into the semiconductor layer structure.

34. (canceled)

35. The semiconductor device of claim 33, wherein the semiconductor layer structure further comprises a trench shield having the second conductivity type that is in between a bottom of the gate trench and a first of the first JFET regions.

36-38. (canceled)

39. The semiconductor device of claim 34, wherein the semiconductor layer structure further comprises a first support shield and a second support shield that each have the second conductivity type and that each extend downwardly from the upper surface of the semiconductor layer structure into the drift region, where the gate trench is in between the first support shield and the second support shield.

40. The semiconductor device of claim 39, wherein the semiconductor layer structure further comprises a third JFET pattern that includes a plurality of third JFET regions having the first conductivity type, wherein a first of the third JFET regions is positioned below the first support shield and a second of the third JFET regions is positioned below the second support shield.

41. The semiconductor device of claim 40, wherein the first of the third JFET regions is spaced-apart from the second of the third JFET regions.

42-83. (canceled)
